(19) United States
(12) Patent Application Publication
(10) Pub. No.: US 2025/0391795 A1
(43) Pub. Date: Dec. 25, 2025

(54) SEMICONDUCTOR ELEMENT, SEMICONDUCTOR DEVICE

(71) Applicant: ROHM CO., LTD., Kyoto (JP)

(72) Inventors: Shogo ITO, Kyoto (JP); Hideshi YOSHIMOTO, Kyoto (JP)

(73) Assignee: ROHM CO., LTD., Kyoto (JP)

(21) Appl. No.: 19/239,076

(22) Filed: Jun. 16, 2025

(30) Foreign Application Priority Data
Jun. 25, 2024 (JP) 2024-102262

(51) Int. Cl. H01L 23/00; H01L 23/31

(52) U.S. Cl. CPC H01L 24/13; H01L 23/3107; H01L 24/05; H01L 24/11; H01L 24/16; H01L 2224/0401; H01L 2224/05022; H01L 2224/05024; H01L 2224/05082; H01L 2224/05166; H01L 2224/05171; H01L 2224/05176; H01L 2224/0518; H01L 2224/05181; H01L 2224/05184; H01L 2224/11464; H01L 2224/11474; H01L 2224/13017; H01L 2224/13026; H01L 2224/13083; H01L 2224/13111; H01L 2224/13147; H01L 2224/13155; H01L 2224/16175; H01L 2924/1815; H01L 2924/35121

(57) ABSTRACT

An electrode terminal of a semiconductor element includes a terminal portion and a pedestal portion. The terminal portion includes a terminal portion rear surface and a terminal portion side surface. The terminal portion side surface intersects with the terminal portion rear surface. The pedestal portion protrudes outwardly from a part of the terminal portion side surface of the terminal portion. The pedestal portion includes a pedestal portion rear surface, a pedestal portion side surface, and a curved surface. The pedestal portion rear surface is in contact with an insulating layer. The pedestal portion side surface intersects with the pedestal portion rear surface and is located outside the terminal portion side surface. The curved surface is disposed between the pedestal portion rear surface and the pedestal portion side surface.

### CROSS REFERENCE TO RELATED APPLICATION

This application is based upon and claims the benefit of priority of the prior Japanese Patent Application No. 2024-102262, filed on Jun. 25, 2024, the entire contents of which are incorporated herein by reference.

### TECHNICAL FIELD

The present disclosure relates to a semiconductor element, and a semiconductor device.

### BACKGROUND ART

Japanese Patent Application Laid-open Publication No. 2020-167330 discloses a semiconductor package that includes a conductive member, a semiconductor device flip-bonded to the conductive member by using Cu pillars on a Cu conductive layer, and a sealing resin that covers a part of the conductive member and the semiconductor device.

### BRIEF DESCRIPTION OF THE DRAWINGS

FIG. 1 is a schematic perspective view of an example of a semiconductor device.

FIG. 2 is a schematic perspective view of the semiconductor device of FIG. 1 seen from the rear side.

FIG. 3 is a schematic plan view showing the internal structure of the semiconductor device of FIG. 1.

FIG. 4 is a schematic cross-sectional view of the semiconductor device along the F4-F4 line of FIG. 3.

FIG. 5 is an enlarged schematic cross-sectional view showing an electrode terminal and surrounding components in the F5 area of FIG. 5.

FIG. 6 is a schematic cross-sectional view showing the electrode terminal and surrounding components along the F6-F6 line of FIG. 5.

FIG. 7 is a schematic cross-sectional view showing the configuration of the electrode terminal of a semiconductor element of FIG. 5.

FIG. 8 is an enlarged schematic cross-sectional view of the electrode terminal of FIG. 7.

FIG. 9 is a schematic cross-sectional view showing an example of the manufacturing process of the semiconductor device of FIG. 4.

FIG. 10 is a schematic cross-sectional view showing a manufacturing process subsequent to FIG. 9.

FIG. 11 is a schematic cross-sectional view showing a manufacturing process subsequent to FIG. 10.

FIG. 12 is a schematic cross-sectional view showing a manufacturing process subsequent to FIG. 11.

FIG. 13 is a schematic cross-sectional view showing a manufacturing process subsequent to FIG. 12.

FIG. 14 is a schematic cross-sectional view showing a manufacturing process subsequent to FIG. 13.

FIG. 15 is a schematic cross-sectional view showing a manufacturing process subsequent to FIG. 14.

FIG. 16 is a schematic cross-sectional view showing a manufacturing process subsequent to FIG. 15.

FIG. 17 is a schematic cross-sectional view showing a manufacturing process subsequent to FIG. 16.

FIG. 18 is a schematic cross-sectional view showing a manufacturing process subsequent to FIG. 17.

FIG. 19 is a schematic cross-sectional view showing a manufacturing process subsequent to FIG. 18.

FIG. 20 is a schematic cross-sectional view showing a manufacturing process subsequent to FIG. 19.

FIG. 21 is an enlarged schematic cross-sectional view showing an electrode terminal and surrounding components of a semiconductor device of a modification example.

FIG. 22 is an enlarged schematic cross-sectional view showing an electrode terminal and surrounding components of a semiconductor device of a modification example.

FIG. 23 is a schematic cross-sectional view showing an electrode terminal and surrounding components of a semiconductor device of a modification example.

### DETAILED DESCRIPTION OF EMBODIMENTS

Below, some embodiments of the present disclosure will be explained with reference to the drawings. For ease of explanation and clarification, components illustrated in the drawings are not necessarily drawn to the same scale. Also, for ease of understanding, hatching lines may be omitted in the cross-sectional views. The appended figures are merely illustrating embodiments of the present disclosure, and shall not be interpreted as limiting the present disclosure. In the present disclosure, such terms as “first” “second” and “third” are used to simply distinguish respective objects from each other, and do not rank those objects against one another.

The detailed description below includes devices, systems, and methods to realize the illustrative embodiments of the present disclosure. This detailed description is provided for explanation, and is not intended to limit embodiments of the present disclosure or application or use of such embodiments.

### EMBODIMENTS

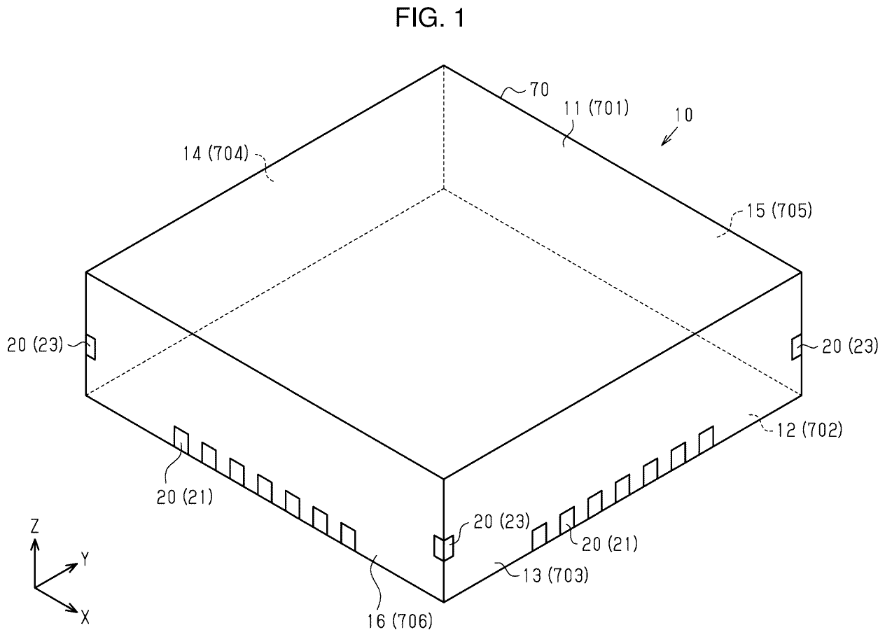

With reference to FIGS. 1 to 8, a semiconductor device 10 of one embodiment will be explained.

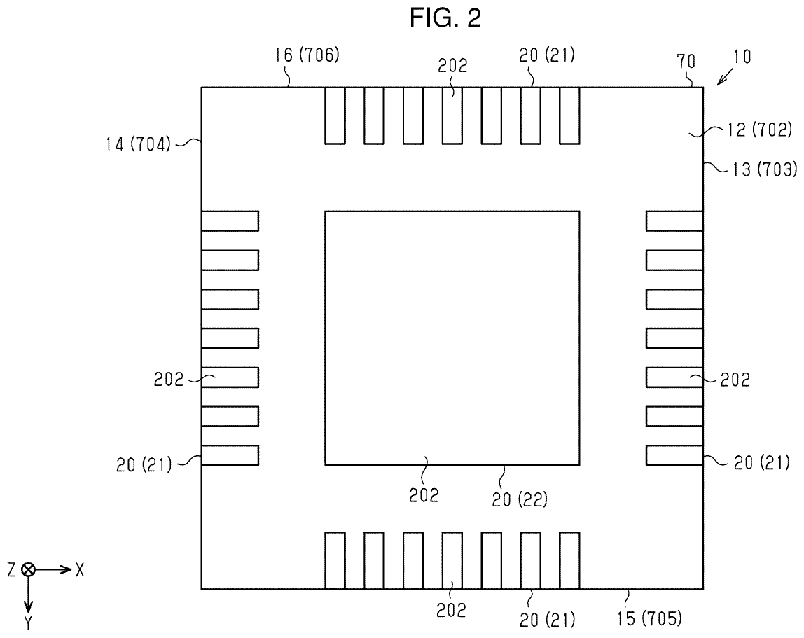

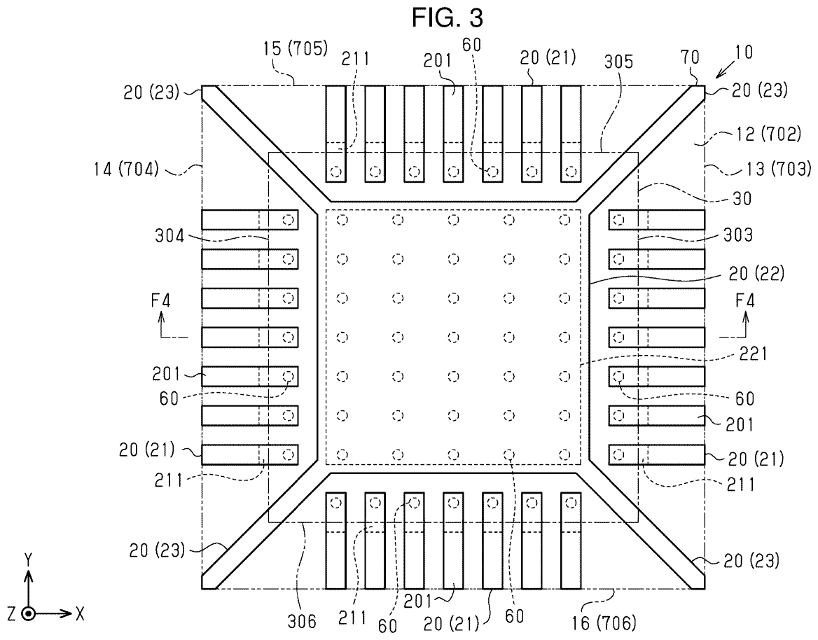

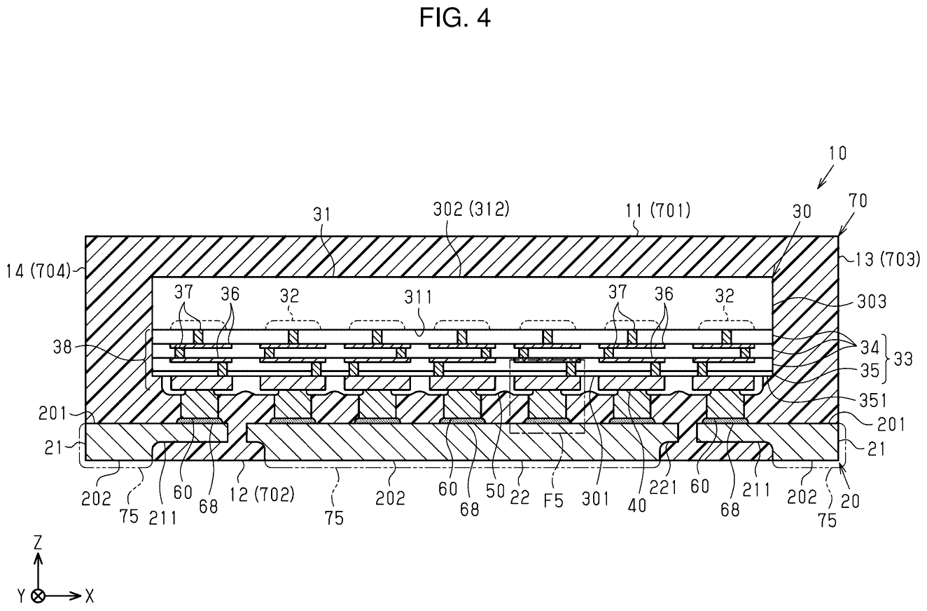

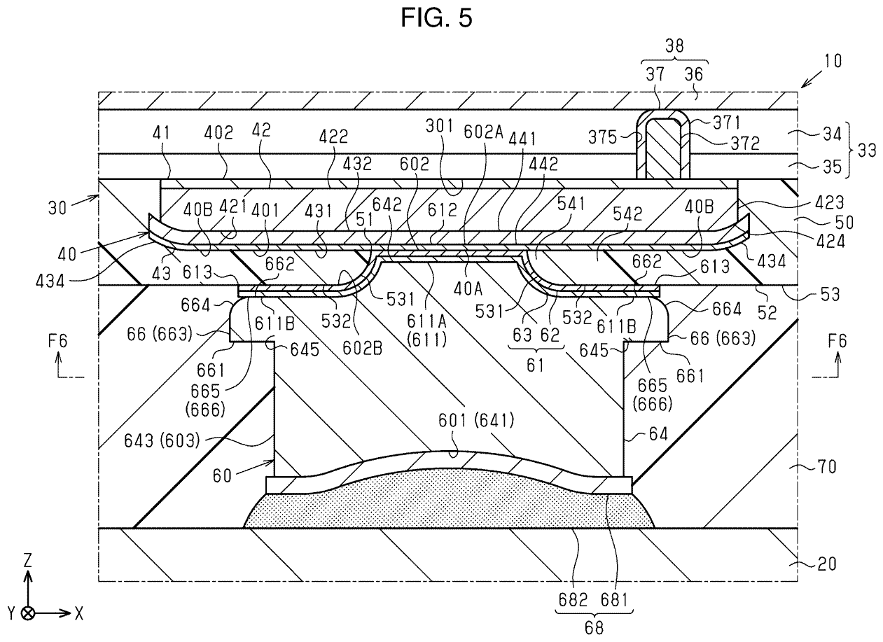

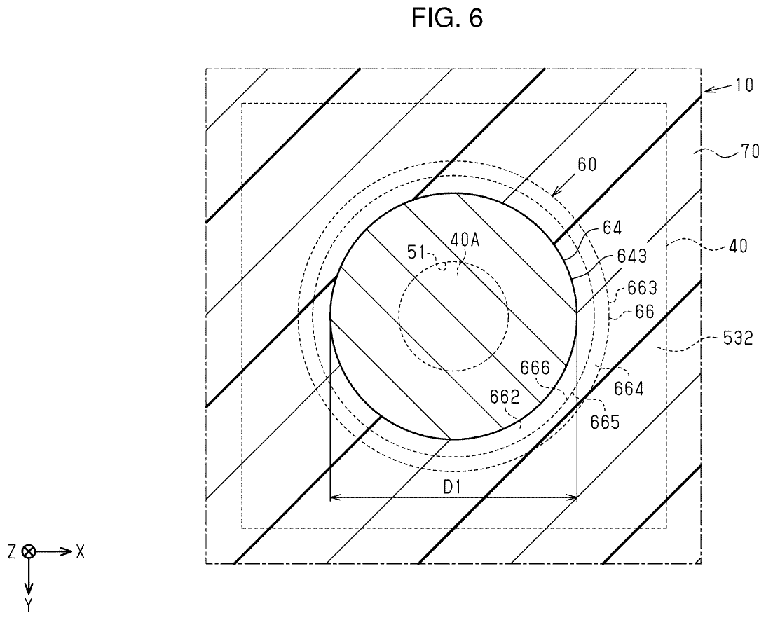

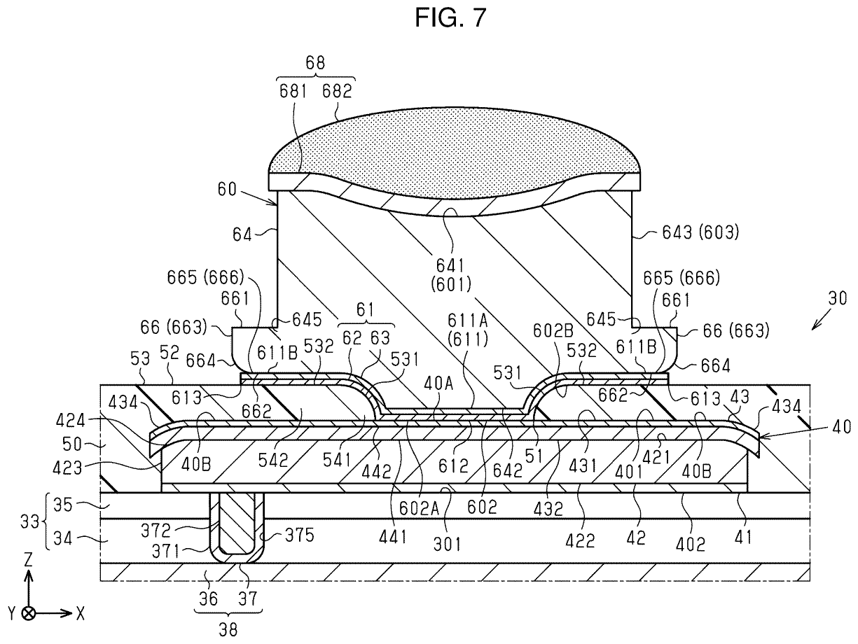

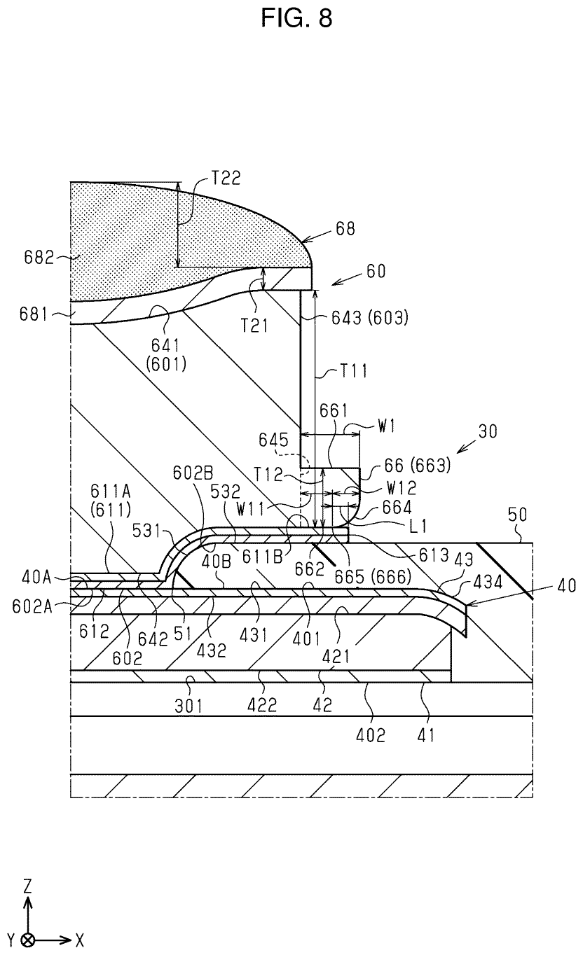

FIG. 1 is a schematic perspective view of an example of the semiconductor device 10. FIG. 2 is a schematic perspective view of the semiconductor device 10 of FIG. 1 seen from the rear side. FIG. 3 is a schematic plan view showing the internal structure of the semiconductor device 10 of FIG. 1. In FIG. 3, a sealing resin 70 is indicated with the two-dot chain line to illustrate the state of a semiconductor element 30 and a connection terminal 20. FIG. 4 is a schematic cross-sectional view of the semiconductor device 10 cut along the F4-F4 line of FIG. 3. FIG. 5 is an enlarged schematic cross-sectional view showing an electrode terminal and surrounding components in the F5 area of FIG. 4. FIGS. 4 and 5 illustrate the semiconductor element 30 with an element surface 301 facing down. FIG. 6 is a schematic cross-sectional view showing the electrode terminal 60 and surrounding components, cut along the F6-F6 line of FIG. 5. FIG. 7 is a schematic cross-sectional view showing the configuration of the electrode element 60 of the semiconductor element 30 of FIG. 5. FIG. 7 illustrates the semiconductor element 30 with the element surface 301 facing up. Also, FIG. 7 shows the state of a bonding layer 68 before bonded to the connection terminal 20. FIG. 8 is an enlarged schematic cross-sectional view of the electrode terminal 60 of FIG. 7. The term “in a plan view” used in the present disclosure means that the semiconductor device 10 is seen from the Z axis direction, which is one of the XYZ axes that are orthogonal to each other as shown in FIG. 1.

### (Schematic Configuration of Semiconductor Device)

As illustrated in FIG. 1, the semiconductor device 10 has a rectangular panel shape with the Z axis direction being the thickness direction. The semiconductor device 10 includes a device front surface 11 that faces the Z axis direction and a device rear surface 12 on the opposite side of the device front surface 11. The semiconductor device 10 includes four device side surfaces 13 to 16 that connect the device front surface 11 and the device rear surface 12 in the Z axis direction. The device side surfaces 13 and 14 constitute two end surfaces of the semiconductor device 10 in the X axis direction, and the device side surfaces 15 and 16 constitute two end surfaces of the semiconductor device 10 in the Y axis direction. In the example illustrated in FIG. 1, the semiconductor device 10 has a square shape in a plan view. The semiconductor device 10 is a surface-mounting package where the device rear surface 12 becomes a mounting surface when mounted onto a circuit substrate (not shown in the figure), for example. In the example illustrated in FIG. 1, the package type of the semiconductor device 10 is QFN (quad flat non-leaded package). The shape of the semiconductor device 10 in a plan view is not limited to the square shape, and may be modified as appropriate. The dimensions of the semiconductor device 10 in the X axis direction, Y axis direction and Z axis direction may be modified as appropriate. The package type of the semiconductor device 10 is not limited to QFN and may be modified as appropriate.

As illustrated in FIGS. 1 to 4, the semiconductor device 10 includes a connection terminal 20. The semiconductor device 10 may include a plurality of connection terminals 20.

The connection terminal 20 includes a connection terminal front surface 201, a connection terminal front surface 201 that faces the Z axis direction, and a connection terminal rear surface 202 on the opposite side of the connection terminal front surface 201. In one example, the connection terminal rear surface 202 is exposed from the device rear surface 12.

The connection terminal 20 may include a lead 21, a pad 22, and a finger 23. In one example, the semiconductor device 10 includes a plurality of leads 21. The number of leads 21 may be modified as appropriate. In one example, the semiconductor device includes one pad 22. The number of pads 22 may be modified as appropriate. In one example, the semiconductor device 10 includes a plurality of fingers 23. The number of fingers 23 may be modified as appropriate. The semiconductor device 10 does not have to include the pad 22. The semiconductor device 10 does not have to include the fingers 23.

The plurality of leads 21 are disposed along the edges of the semiconductor device 10. The plurality of leads 21 are exposed from the device rear surface 12. The plurality of leads 21 may be disposed along at least one of the device side surfaces 13 to 16. In one example, the plurality of leads 21 are disposed along each of the device side surfaces 13 to 16. The plurality of leads 21 may be exposed from the corresponding device side surfaces 12.

In one example, the plurality of leads 21 respectively have a band shape that extends in the direction orthogonal to the corresponding device side surfaces 13 to 16 in a plan view. The planar shape of the plurality of leads 21 may be modified as appropriate. In one example, the plurality of leads 21 each include a protrusion 211 that protrudes toward the center of the semiconductor device 10 on the connection terminal front surface 201.

The pad 22 is disposed such that it is exposed from the device rear surface 12 of the semiconductor device 10. In one example, the pad 22 is disposed at the center of the device rear surface 12. In one example, the pad 22 has a rectangular panel shape in a plan view. In one example, the pad 22 has four sides that are parallel to the device side surfaces 13 to 16 in a plan view. In one example, the pad 22 includes protrusions 221 that protrude toward the device side surfaces 13 to 16 from the edges closer to the connection terminal front surface 201.

The plurality of fingers 23 are drawn from the pad 22 toward the device side surfaces 13 to 16 of the semiconductor device 10 in a plan view. In one example, the plurality of fingers 23 are drawn from the four corners of the rectangular pad 22 toward the four corners of the semiconductor device 10, respectively. The plurality of fingers 23 may be exposed from the device side surfaces 13 to 16.

The connection terminal 20 is made of a conductive material. The conductive material may be a material that includes at least one of Ti (titanium), TiN (titanium nitride), Au (gold), Ag (silver), Cu (copper), Al (aluminum), and W (tungsten) as appropriate, for example. The connection terminal 20 is formed by etching a plate material made of a conductive material, for example. The forming method of the connection terminal 20 may be modified as appropriate. In one example, the connection terminal 20 may be formed by performing a punching process, bending process, or the like.

The semiconductor device 10 includes a semiconductor element 30. The semiconductor element 30 is disposed inside the semiconductor device 10. The semiconductor element 30 is disposed at the center of the semiconductor device 10 in a plan view. The semiconductor element 30 is disposed inside the semiconductor device 10 such that it overlaps the entire pad 22 and the inner ends of the plurality of leads 21.

The semiconductor element 30 has a rectangular panel shape with the Z axis direction being the thickness direction. The semiconductor element 30 includes an element front surface 301 that faces the Z axis direction, and an element rear surface 302 on the opposite side of the element front surface 301. The semiconductor element 30 includes element side surfaces 303 to 306 that connect the element front surface 301 and the element rear surface 302 in the Z axis direction. The element side surfaces 303 and 304 constitute two end surfaces of the semiconductor element 30 in the X axis direction, and the element side faces 305 and 306 constitute two end surfaces of the semiconductor element 30 in the Y axis direction.

The semiconductor element 30 includes a plurality of electrode terminals 60 on the element front surface 301. The semiconductor element 30 is disposed such that the plurality of electrodes terminals 60 face the connection terminal 20. It can be said that the semiconductor element 30 is disposed such that the element front surface 301 faces the connection terminal 20. The plurality of electrode terminals 60 are mechanically and electrically connected to the connection terminal 20 by a bonding layer 68. It can be said that the semiconductor element 30 is flip-chip mounted onto the connection terminal 20.

The semiconductor device 10 includes a sealing resin 70. The sealing resin 70 constitutes the exterior structure of the semiconductor device 10. More specifically, the sealing resin 70 has a rectangular panel shape with the Z axis direction being the thickness direction. The sealing resin 70 has a sealing front surface 701, a sealing rear surface 702 on the opposite side of the sealing surface 701 in the Z-axis direction, and four sealing side surfaces 703 to 706 connecting the sealing front surface 701 and the sealing rear surface 702 in the Z-axis direction. The sealing surface 701 constitutes the device front surface 11, and the sealing rear surface 702 constitutes the device rear surface 12. The sealing side surface 703 constitutes the device side surface 13, the sealing side surface 704 constitutes the device side surface 14, the sealing side surface 705 constitutes the device side surface 15, and the sealing side surface 706 constitutes the device side surface 16.

As shown in FIG. 4, the sealing resin 70 covers the semiconductor element 30. The sealing resin 70 is made of an insulating material such as epoxy resin. The sealing resin 70 may be colored black, for example. The sealing resin 70 covers the entire semiconductor element 30 and a part of the connection terminal 20. It can be said that the sealing resin 70 seals the semiconductor element 30 and a part of the connection terminal 20. It can be said that the sealing resin 70 supports the connection terminal 20.

A conductive film 75 shown by the two-dot chain line in FIG. 4 may be provided on the surface of the connection terminal 20 exposed from the sealing resin 70. The conductive film 75 may be a plating film containing Sn (tin), for example. The conductive film 75 may include a plurality of plating films. In one example, the conductive film 75 may include a plurality of plating films layered in the order of Ni (nickel), Pd (palladium), and Au.

### (Schematic Configuration of Semiconductor Element)

As shown in FIG. 4, the semiconductor device 30 includes a substrate 31. The substrate 31 is constituted of a semiconductor substrate, for example. In one example, the substrate 31 is a semiconductor substrate made of a material containing Si (silicon). The substrate 31 may be made of a wide band gap semiconductor. A wide bandgap semiconductor is a semiconductor that has a bandgap larger than the bandgap of Si. Examples of wide band gap semiconductors include GaN (gallium nitride) and SiC (silicon carbide). In this embodiment, the substrate 31 is made of a Si silicon chip. The substrate 31 may have a multi-layer structure including a semiconductor substrate and an epitaxial layer. The substrate 31 may be constituted of an epitaxial layer.

The substrate 31 has a rectangular panel shape with the Z axis direction being the thickness direction. The substrate 31 includes a substrate front surface 311 and a substrate rear surface 312 on the opposite side of the substrate front surface 311. The substrate 31 is disposed such that the substrate front surface 311 faces the connection terminal front surface 201 of the connection terminal 20. In one example, the substrate rear surface 312 constitutes the element rear surface 302.

The semiconductor element 30 includes one or more device regions 32 defined on the substrate front surface 311 of the substrate 31. In FIG. 4, a plurality of device regions 32 are indicated with the broken line. The substrate front surface 311 of the substrate 31 can be considered a device front surface. In one example, the substrate 31 has a plurality of device regions 32 defined thereon.

The number and arrangement of the device regions 32 may be modified as appropriate. The device regions 32 may include function devices disposed inside and outside the substrate 31. The function devices may include at least one of a semiconductor switching device, a semiconductor rectifier device, and a receptor device. The function devices may also include a circuit network that has a combination of at least two of the semiconductor switching device, semiconductor rectifier device and receptor device.

The semiconductor switching device may include at least one of a metal insulator semiconductor field effect transistor (MISFET), a bipolar junction transistor (BJT), an insulated gate bipolar junction transistor (IGBT), and a junction field effect transistor (JFET). The semiconductor rectifier device may include at least one of a pn junction diode, a pin junction diode, a Zener diode, a Schottky barrier diode, and a fast recovery diode. The receptor device may include at least one of a resistance, capacitor, inductor and fuse.

The semiconductor element 30 includes an insulating film 33 disposed on the substrate front surface 311. The insulating film 33 is sandwiched between the connection terminal 20 and the substrate 31. In one example, the insulating film 33 covers the entire substrate front surface 311 in a plan view and is in contact with the substrate front surface 311.

The insulating film 33 may include a plurality of interlayer insulating films 34 and top insulating film 35.

The number of interlayer insulating films 34 may be any number. In one example, the number of interlayer insulating films 34 may be 2 or greater but no more than 25. Each of the plurality of interlayer insulating films 34 may have a single-layer structure or a multilayer structure including at least one of a SiO2 (silicon oxide) film and a SiN (silicon nitride) film. In one example, the plurality of interlayer insulating films 34 each have a single-layer structure made of a SiO2 film.

The top insulating film 35 constitutes the end insulating film of the insulating film 33, and covers the uppermost interlayer insulating film 34. The top insulating film 35 may be referred to as a “inorganic insulating film” or “passivation film”. The top insulating film 35 may have a single-layer structure including at least one of a SiO2 film and a SiN film.

The top insulating film 35 may be made of an insulating material that at least differs from the insulating material of the uppermost interlayer insulating film 34. In one example, the top insulating film 35 has a single-layer structure made of a SiN film. The top insulating film 35 has a flat surface extending along the substrate front surface 311. In one example, the top insulating film 35 may have a thickness that is at least smaller than that of the uppermost interlayer insulating film 34. The top insulating film 35 may have a multi-layer structure of an SiO2 film and an SiN film. In one example, the surface of the top insulating film 35 on the opposite side of the substrate 31 may constitute the element front surface 301 of the semiconductor element 30.

The semiconductor element 30 may include a plurality of interlayer wiring lines 36 disposed in the insulating film 33. The plurality of interlayer wiring lines 36 are wiring line films disposed on any one of the interlayer insulating films 34 below the top insulating film 35. The plurality of interlayer wiring lines 36 may be arranged in any appropriate manner. The semiconductor element 30 may include a plurality of via wiring lines 37 connected to the plurality of interlayer wiring lines 36. The plurality of via wiring lines 37 run through the interlayer insulating films 34, respectively. The plurality of interlayer wiring lines 36 and the plurality of via wiring lines 37 constitute a multilayer wiring structure 38, together with the plurality of interlayer insulating films 34. The interlayer wiring lines 36 are made of a material containing at least one of Al, Cu, Ti, and W.

The semiconductor element 30 includes a plurality of electrodes 40 disposed on the element front surface 301. The element front surface 301 is constituted of the surface of the insulating film 33, more specifically, the top insulating film 35. Therefore, it can be said that the semiconductor element 30 includes the plurality of electrodes 40 disposed on the surface of the insulating film 33. The plurality of electrodes 40 respectively constitute terminal lines of the multi-layer wiring structure 38. The plurality of electrodes 40 may be arranged in any appropriate manner. The plurality of electrodes 40 may be arranged linearly in a plan view, or may have an island-like shape. The plurality of electrodes 40 may have a relatively wide island portion and a relatively narrow line portion extending in a line shape from the island portion in a plan view.

The plurality of electrodes 40 respectively have a thickness greater than that of the top insulating film 35. The plurality of electrodes 40 may respectively have a thickness greater than that of each interlayer wiring line 36. The plurality of wiring layers have the same configuration as each other except for their locations and routing arrangements.

The semiconductor element 30 includes an insulating layer 50 disposed on the element front surface 301. The insulating layer 50 covers a surface 351 of the top insulating film 35 and part of the electrodes 40. The insulating layer 50 may be made of an insulating material such as an epoxy resin, a phenolic resin, or a polyimide resin. The insulating layer 50 has openings 51 through which part of the electrodes 40 is exposed. In one example, the openings 51 may each have a circular shape in a plan view.

The semiconductor element 30 includes a plurality of electrode terminals 60. The plurality of electrode terminals 60 are provided for the plurality of electrodes 40, respectively. The electrode terminals 60 are respectively in contact with the exposed parts of the electrodes 40. The electrode terminals 60 partially overlap the insulating layer 50 in a plan view. It can be said that the semiconductor element 30 includes electrode terminals 60 that are in contact with the exposed parts of the electrodes 40 and partially overlap the insulating layer 50 in a plan view. The electrode terminals 60 are electrically connected to the electrodes 40. It can be said that the semiconductor element 30 includes electrode terminals 60 electrically connected to the electrodes 40.

The plurality of electrode terminals 60 protrude in the Z axis direction from electrode top surfaces 401 of the electrodes 40. The plurality of electrode terminals 60 each have a pillar shape. In one example, the electrode terminals 60 have a column shape. The plurality of electrode terminals 60 are disposed between the electrodes 40 and the connection terminal 20.

The semiconductor element 30 includes the bonding layer 68 disposed on terminal front surfaces 601 of the electrode terminals 60. The bonding layer 68 is disposed between the electrode terminals 60 and the connection terminal 20. The electrode terminals 60 are mechanically and electrically connected to the connection terminal 20 by the bonding layer 68.

### (Detailed Description of Electrode Terminal and Surrounding Structure)

The electrode terminals 60 and surrounding configurations thereof will be described in detail with reference to FIGS. 5 to 8.

### (Electrode)

One example of the electrode 40 illustrated in FIGS. 5 to 8 will be explained. The shape, configuration, and material of the electrode 40 may each be modified as appropriate.

The electrode 40 includes an electrode top surface 401 and an electrode bottom surface 402 on the opposite side of the electrode top surface 401. The electrode bottom surface 402 is in contact with the surface 351 of the top insulating film 35. As illustrated in FIG. 6, in one example, the electrode 40 may have a rectangular shape in a plan view.

The electrode 40 includes a wiring barrier film 41 disposed the surface 351 of the top insulating film 35. The wiring barrier film 41 selectively covers the top insulating film 35. The wiring barrier film 41 may be made of a material containing at least one of Ti, TiN, Ta (tantalum), W, Mo (molybdenum), and Cr (chromium). The wiring barrier film 41 may have a multi-layer structure or single-layer structure including at least one of a Ti film and a TiN film. In one example, the wiring barrier film 41 has a single-layer structure made of a material containing Ti.

The electrode 40 includes a wiring electrode 42 that covers the wiring barrier film 41. The wiring electrode 42 constitutes the main body of the electrode 40. The wiring electrode 42 may cover the entire wiring barrier film 41 in a cross-sectional view and plan view. The wiring electrode 42 may be made of a material containing at least one of Al and Cu.

The wiring electrode 42 includes a wiring top surface 421, a wiring bottom surface 422 on the opposite side of the wiring top surface 421, and wiring side surfaces 423 connecting the wiring top surface 421 and the wiring bottom surface 422. The wiring bottom surface 422 faces the surface of the top insulating film 35. In one example, the wiring electrode 42 has upper end corners 424 that are rounded. The wiring upper end corners 424 are down-sloping in an arc shape from the wiring top surface 421 to the wiring side surfaces 423 at the periphery of the wiring upper surface 421.

The electrode 40 includes a cover electrode 43 that covers the wiring electrode 42. The cover electrode 43 has a film shape that covers the wiring electrode 42. The cover electrode 43 includes a cover top surface 431 and a cover bottom surface 432 on the opposite side of the cover top surface 431. The cover bottom surface 432 is in contact with the wiring top surface 421 of the wiring electrode 42. The cover electrode 43 includes a rounded portion 434 in a film shape that covers the wiring top end corners 424, warping along the wiring top end corners 424.

In this embodiment, the cover electrode 43 may have a multi-layer structure in which a plurality of metal films are laminated. The cover electrode 43 may include a first metal film 441 and a second metal film 442 laminated on the wiring electrode 42 in this order. The first metal film 441 covers the entire wiring top surface 421. The first metal film 441 constitutes the cover bottom surface 432 of the cover electrode 43. In one example, the first metal film 441 is made of a material containing Ni. The second metal film 442 covers the entire first metal film 441. The second metal film 442 constitutes the cover top surface 431 of the cover electrode 43. In one example, the second metal film 442 is made of a material containing Pd.

The electrodes 40 are electrically connected to the interlayer wiring line 36 through via wiring 37. The via wiring 37 is embedded in a via hole 375 disposed in the insulating film 33. In FIGS. 5 and 7, the via hole 375 run through the top insulating film 35 and the interlayer insulating film 34. The via wiring 37 has a multi-layer structure including a barrier film 371 and a via main body 372. The barrier film 371 covers the inner surfaces of the via hole 375. In one example, the barrier film 371 is made of a material containing Ti. The via main body 372 is embedded in the via hole 375 with the barrier film 371 disposed therebetween. In one example, the via main body 372 is made of a material containing W.

### (Insulating Layer)

As illustrated in FIGS. 5 and 7, the insulating layer 50 covers the surface 351 of the top insulating film 35 and part of the electrode 40.

The insulating layer 50 has an opening 51 through which a part of the electrode 40 is exposed. In one example, the opening 51 has a circular shape in a plan view. The electrode 40 includes an exposed part 40A exposed through the opening 51 of the insulating layer 50, a non-exposed part 40B covered by the insulating layer 50.

The insulating layer 50 includes a periphery 52 of the opening 51. The periphery 52 overlaps the electrode 40 in a plan view. The periphery 52 may be a part that covers the electrode 40. A surface 53 of the periphery 52 includes a first surface 531 and a second surface 532. The second surface 532 is a surface outside the first surface 531.

The periphery 52 includes an opening edge 541 that constitutes the opening 51 through which part of the electrode 40 is exposed. The opening edge 541 is a ring-shaped area that surrounds the exposed part 40A of the electrode 40 by the circular opening 51 in a plan view.

The periphery 52 includes a flat portion 542 that is located outside the opening edge 541 and that has a flat surface. In one example, the second surface 532 includes the surface of the flat portion 542. The first surface 531 includes a surface that is sloping down in an arc shape from the second surface 532 into the opening 51. It can be said that the first surface 531 is the surface of the opening edge 541. That is, it can be said that the surface of the opening edge 541 is a surface that is sloping down in an arc shape from the surface of the flat portion 542 into the opening 51. It can be said that the surface 53 of the periphery 52 includes the flat second surface 532 and the first surface 531 located inside the second surface 532 and sloping toward the exposed part 40A of the electrode 40.

### (Electrode Terminal)

As illustrated in FIGS. 5 to 8, the electrode terminal 60 is electrically connected to the electrode 40 exposed through the opening 51 of the insulating layer 50. The electrode 40 includes the exposed part 40A exposed through the opening 51 of the insulating layer 50. The electrode terminal 60 is electrically connected to the exposed part 40A of the electrode 40.

The electrode terminal 60 protrudes in the Z axis direction from the electrode top surface 401 of the electrode 40. The electrode terminal 60 protrudes in the Z axis direction from the surface 53 of the periphery 52 of the insulating layer 50. The electrode terminal 60 has a pillar shape. In one example, the electrode terminal 60 has a column shape.

The electrode terminal 60 is in contact with the exposed part 40A of the electrode 40 exposed through the opening 51 of the insulating layer 50. The electrode terminal 60 partially overlaps the insulating layer 50 when viewed from the thickness direction. The electrode terminal 60 is disposed across the exposed part 40A of the electrode 40 and the periphery 52 of the opening 51 of the insulating layer 50.

The electrode terminal 60 includes a terminal rear surface 602 that faces the electrode 40, and a terminal front surface 601 on the opposite side of the terminal rear surface 602. The electrode terminal 60 includes a terminal side surface 603 that connects the terminal rear surface 602 and the terminal front surface 601. The terminal rear surface 602 includes a first portion 602A that is in contact with the exposed part 40A of the electrode 40, and a second portion 602B that is in contact with the periphery 52 of the insulating layer 50. The second portion 602B of the terminal rear surface 602 surrounds the first portion 602A of the terminal rear surface 602.

### (Base Layer)

The electrode terminal 60 may include a base layer 61. The base layer 61 is disposed across the exposed part 40A of the electrode 40 and the periphery 52 of the opening 51 in the insulating layer 50. The base layer 61 is in contact with both the exposed part 40A of the electrode 40 and the periphery 52 of the insulating layer 50. The base layer 61 includes a top surface 611 and a bottom surface 612 on the opposite side of the top surface 611. The bottom surface 612 of the base layer 61 is in contact with both the exposed part 40A of the electrode 40 and the surface 53 of the periphery 52. In one example, the bottom surface 612 of the base layer 61 constitutes the terminal rear surface 602 of the electrode terminal 60. The base layer 61 includes an outer periphery 613.

The top surface 611 of the base layer 61 includes a first region 611A and a second region 611B. It can be said that the base layer 61 has the top surface 611 that includes the first region 611A and the second region 611B. The first region 611A overlaps the exposed part 60A of the electrode 40 in a plan view. The first region 611A overlaps a part of the periphery 52 of the opening 51 in an insulating layer 50. In one example, the first region 611A overlaps the first surface 531 of the insulating layer 50. The first region 611A overlaps the exposed part 40A of the electrode 40 and the first surface 531 of the insulating layer 50 in a plan view. The second region 611B is disposed on the outside of the first region 611A. The second region 611B is a ring-shaped region that surrounds the first region 611A. The second region 611B overlaps the flat portion 542 of the insulating layer 50 in a plan view. That is, the second region 611B overlaps the second surface 532 of the insulating layer 50 in a plan view. It can be said that the second region 611B is a flat surface. In a plan view, the area of the first region 611A is larger than the area of the second region 611B

The base layer 61 may have a multi-layer structure or single-layer structure. In one example, the base layer 61 has a multi-layer structure including a barrier layer 62 and a seed layer 63. The layer structure of the base layer 61 may be modified as appropriate.

The barrier layer 62 is in contact with both the exposed part 40A of the electrode 40 and the surface 53 of the periphery 52 of the insulating layer 50. In one example, the barrier layer 62 constitutes the bottom surface 612 of the base layer 61. The barrier layer 62 may be made of a material containing at least one of Ti, TiN, Ta, W, Mo, Cr, and Ru (ruthenium). In one example, the barrier layer 62 is made of a material containing Ti. The barrier layer 62 may have a multi-layer structure or single-layer structure. In one example, the thickness of the barrier layer 62 may be 0.15 μm.

The seed layer 63 covers the barrier layer 62. The seed layer 63 covers the entire barrier layer 62. In one example, the seed layer 63 constitutes the top surface 611 of the base layer 61. The seed layer 63 is made of a material containing Cu. The seed layer 63 may have a multi-layer structure or single-layer structure. In one example, the thickness of the seed layer 63 may be 0.25 μm.

In one example, the barrier layer 62 and the seed layer 63 are sputter layers. The barrier layer 62 and the seed layer 63 are formed by sputtering. That is, in one example, the barrier layer 62 is a sputter layer. The base layer 61 is formed by sputtering. In one example, the size of the barrier layer 62 and the size of the seed layer 63 are the same in a plan view. Therefore, the side face of the barrier layer 62 is flush with the side face of the seed layer 63. The barrier layer 62 may be larger than the seed layer 63 in a plan view. The barrier layer 62 may be smaller than the seed layer 63 in a plan view. It can be said that the outer periphery 613 of the base layer 61 is the outer periphery of the barrier layer 62. It can be said that the outer periphery 613 of the base layer 61 is the outer periphery of the seed layer 63.

### (Terminal Portion, Pedestal Portion)

The electrode terminal 60 includes a terminal portion 64 and a pedestal portion 66. In one example, the terminal portion 64 and the pedestal portion 66 are bonded to the top surface 611 of the base layer 61. It can be said that the electrode terminal 60 includes the terminal portion 64 and the pedestal portion 66 bonded to the top surface of the base layer 61. The terminal portion 64 is bonded to the first region 611A of the top surface 611 of the base layer 61. The pedestal portion 66 is bonded to the second region 611B of the top surface 611 of the base layer 61. It can be said that the electrode terminal 60 includes the terminal portion 64 bonded to the first region 611A of the top surface 611 of the base layer 61, and the pedestal portion 66 bonded to the second region 611B of the top surface 611 of the base layer 61. The second region 611B is disposed outside the first region 611A. It can be said that the pedestal portion 66 is disposed outside the terminal portion 64.

The terminal portion 64 rises up from the first region 611A. The terminal portion 64 has a pillar shape. In one example, the terminal portion 64 has a column shape. The shape of the terminal portion 64 may be modified as appropriate.

The terminal portion 64 includes a terminal portion front surface 641 and a terminal portion rear surface 642 on the opposite side of the terminal portion front surface 641. The terminal portion rear surface 642 faces the electrode 40. It can be said that the terminal portion 64 includes the terminal portion rear surface 642 that faces the electrode 40. The terminal portion 64 includes a terminal portion side surface 643 that intersect with the terminal portion rear surface 642. The terminal portion 64 may include a recess 644. The recess 644 is recessed from the terminal portion front surface 641.

A part of the terminal portion rear surface 642 faces the exposed part 40A of the electrode 40. A part of the terminal portion rear surface 642 faces the periphery 52 of the insulating layer 50. It can be said that the terminal portion 64 includes the terminal portion rear surface 642 that faces the exposed part 40A of the electrode and the periphery 52 of the insulating layer 50. The terminal portion rear surface 642 is in contact with the top surface 611 of the base layer 61. The electrode portion 64 is electrically connected to the base layer 61. The base layer 61 is electrically connected to the exposed part 40A of the electrode 40. Thus, the terminal portion 64 is electrically connected to the electrode 40.

The pedestal portion 66 is connected to the terminal portion 64. The pedestal portion 66 protrudes outwardly from the terminal portion side face 643 of the terminal portion 64 toward the outside of the terminal portion 64. The pedestal portion 66 protrudes outwardly from a part 645 of the terminal portion side surface 643 of the terminal portion 64 closer to the terminal portion rear surface 642 of the terminal portion 64. As illustrated in FIG. 6, the pedestal portion 66 is formed around the entire terminal portion 64 along the terminal portion side surface 643. It can be said that the pedestal portion 66 has a ring shape in a plan view.

The pedestal portion 66 includes a pedestal portion rear surface 662. The pedestal portion 662 faces the surface 53 of the periphery 52 of the insulating layer 50. It can be said that the pedestal portion 66 includes the pedestal portion rear surface 662 that faces the insulating layer 50. The pedestal portion rear surface 662 is in contact with the top surface 611 of the base layer 61. The pedestal portion rear surface 662 is in contact with the second region 611B of the top surface 611 of the base layer 61. It can be said that the pedestal portion 66 is bonded to the top surface 611 of the base layer 61 by the pedestal portion rear surface 662.

The pedestal portion 66 includes a pedestal portion front surface 661 on the opposite side of the pedestal portion rear surface 662. The pedestal portion front surface 661 intersects with the terminal portion side surfaces 643 of the terminal portion 64.

The pedestal portion 66 includes a pedestal portion side surface 663. The pedestal portion side surface 663 intersects with the pedestal portion rear surface 662. It can be said that the pedestal portion 66 includes the pedestal portion side surface 663 that intersects with the pedestal portion rear surface 662. The pedestal portion side surface 663 intersects with the pedestal portion front surface 661. It can be said that the pedestal portion 66 includes the pedestal portion side surface 663 that intersects with the pedestal portion front surface 661.

The pedestal portion 66 includes a curved surface 664. The curved surface 664 is disposed between the pedestal portion rear surface 662 and the pedestal portion side surface 663. It can be said that the curved surface 664 is a surface that connects the pedestal portion rear surface 662 and the pedestal portion side surface 663. The curved surface 664 is curving away from the pedestal portion 66. The curved surface 664 may be a surface that outwardly protrudes in an arc shape. The sealing resin 70 fills up the space between the curved surface 664 of the pedestal portion 66 and the insulating layer 50. The sealing resin 70 also fills up the space between the curved surface 664 of the pedestal portion 66 and the base layer 61.

As shown in FIG. 8, the pedestal portion rear surface 662 includes an outer periphery 665. The outer periphery 665 is an area of the pedestal portion rear surface 662 that is in contact with the top surface 611 of the base layer 61 and that is closest to the pedestal portion side surface 663. The pedestal portion rear surface 662 is connected to the pedestal portion side surface 663 by the curved surface 664. The curved surface 664 is located inside the electrode terminal 60 than the pedestal portion side surface 663. The pedestal portion 66 protrudes outwardly from the terminal portion side face 643 of the terminal portion 64 toward the outside of the terminal portion 64. Thus, the outer periphery 665 of the pedestal portion rear surface 662 is located between the terminal portion side surface 643 of the terminal portion 64 and the pedestal portion side surface 663 of the pedestal portion 66 in a plan view.

The outer periphery 613 of the base layer 61 may be located on the outside of terminal portion side surface 643 of the terminal portion 64 in a plan view. The outer periphery 613 of the base layer 61 may be located on the outside of the outer periphery 665 of the pedestal portion rear surface 662 of the pedestal portion 66 in a plan view. In one example, the outer periphery 613 of the base layer 61 may be located between the outer periphery 665 of the pedestal portion rear surface 662 and the pedestal portion side face 663 in a plan view.

The pedestal portion rear surface 662 of the pedestal portion 66 is connected to the curved surface 664 of the pedestal portion 66. It can be said that the outer periphery 665 of the pedestal portion rear surface 662 is the inner periphery 666 of the curved surface 664. It can be said that the inner periphery 666 of the curved surface 664 is located between the terminal portion side surface 643 of the terminal portion 64 and the pedestal portion side surface 663 of the pedestal portion 66 in a plan view. It can be said that the inner periphery 666 of the curved surface 664 is located inside the outer periphery 613 of the base layer 61. It can be said that the inner periphery 666 of the curved surface 664 is located between the outer periphery 613 of the base layer 61 and the terminal portion side surface 643 of the terminal portion 64 in a plan view.

The terminal portion 64 and the pedestal portion 66 are made of the same material. In one example, the terminal portion 64 and the pedestal portion 66 are made of a material containing Cu. The terminal portion 64 and the pedestal portion 66 may be physically integrated into one body. In one example, the terminal portion 64 and the pedestal portion 66 are a plating layer. The terminal portion 64 and the pedestal portion 66 are formed by plating.

### (Bonding Layer)

The semiconductor element 30 may include a bonding layer 68 disposed on the terminal front surface 601. The bonding layer 68 may be used for external connection. In one example, the bonding layer 68 is used to mount the semiconductor element 30 onto the connection terminal 20.

The bonding layer 68 may include a first layer 681 and a second layer 682. The first layer 681 is disposed on the terminal front surface 601 of the electrode terminal 60. The first layer 681 of the bonding layer 68 covers the terminal front surface 601 of the electrode terminal 60. The first layer 681 of the bonding layer 68 is in contact with the terminal front surface 601 of the electrode terminal 60. In one example, the first metal layer 681 of the bonding layer 68 may be made of a material containing Ni or Fe. The first layer 681 may be a barrier layer.

The second layer 682 is disposed on the first layer 681. The second layer 682 is in contact with the first layer 681. It can be said that the bonding layer 68 has a multi-layer structure including the first layer 681 and the second layer 682 disposed on the first layer 681. The second layer 682 may be made of a solder containing Sn. In one example, the second layer 682 may include SnAg. As illustrated in FIG. 7, in the state before the electrode terminal 60 is bonded to the connection terminal 20, the second layer 682 has a curved surface with an arc profile.

The first layer 681 of the bonding layer 68 is interposed between the second layer 682 of the bonding layer 68 and the terminal portion 64 of the electrode terminal 60. The second layer 682 may be made of a solder. The first layer 681 of the bonding layer 68 may be made of a metal material that suppresses a chemical reaction between the second layer 682 of the bonding layer 68 and the terminal portion 64 of the electrode terminal 60. In one example, the first layer 681 may be made of a material containing Ni, given that the terminal portion 64 contains Cu, and the second layer 682 contain Sn.

As shown in FIG. 6, the size of the electrode terminal 60, that is, the diameter D1 of the electrode terminal 60, may be represented as the diameter of the terminal portion 64 at the terminal portion side surface 643, i.e., the size of the terminal portion 64, in one example. The diameter (D1) of the electrode terminal 60 may be 10 μm or greater and less than or equal to 150 μm.

As shown in FIG. 8, the thickness T11 of the terminal portion 64 may, in one example, be represented as the distance in the thickness direction from the top surface 611 of the base layer 61 above the periphery 52 of the insulating layer 50 to the upper end of the terminal portion side surface 643. In one example, the thickness (T11) of the terminal portion 64 may be 10 μm or greater and less than or equal to 100 μm.

The thickness T12 of the pedestal portion 66 may be represented as the distance between the pedestal portion rear surface 662 to the pedestal portion front surface 661 in the thickness direction. The thickness (T12) of the pedestal portion 66 may be 5 μm or greater and less than or equal to 20 μm. In one example, the thickness (T12) of the pedestal portion 66 may be 10 μm.

The width W1 of the pedestal portion 66 may be represented as the length of the pedestal portion 66 in the outward direction in which the pedestal portion 66 protrudes. The width W1 of the pedestal portion 66 may be represented as the distance from the terminal portion side surface 643 of the terminal portion 64 to the pedestal portion side surface 663 of the pedestal portion 66 in a direction orthogonal to the thickness direction, or the X-axis direction, for example. The width W1 of the pedestal portion 66 may be 10 μm or greater and less than or equal to 40 μm.

The width W11 of the pedestal portion rear surface 662 of the pedestal portion 66 in the direction orthogonal to the thickness direction, or the X axis direction, for example, may be represented as the distance between the terminal portion side surface 643 of the terminal portion 64 and the outer periphery 665 of the pedestal portion rear surface 662 of the pedestal portion 66 in a plan view. The width W11 of the pedestal portion rear surface 662 may be 8 μm or more and 35 μm or less. In one example, the width W11 of the pedestal portion rear surface 662 may be 8 μm.

The width W11 of the pedestal portion rear surface 662 may be larger than the width W12 of the curved surface 664 in a plan view. The width W12 of the curved surface 664 may be the distance between the inner periphery 666 of the curved surface 664 and the pedestal portion side face 663 of the pedestal portion 66. It can be said that the width W12 of the curved surface 664 is the distance between the outer periphery 665 of the pedestal portion rear surface 662 and the pedestal portion side face 663 of the pedestal portion 66. In one example, the width W12 of the curved surface 664 may be lum or greater and less than or equal to 4 μm. The width W11 of the pedestal portion rear surface 662 may be larger than the distance L1 between the inner periphery 666 of the curved surface 664 and the outer periphery 613 of the base layer 61 in a plan view. In one example, the distance L1 between the inner periphery 666 of the curved surface 664 and the outer periphery 613 of the base layer 61 may be less than or equal to 2 μm in a plan view.

It can be said that the bonding layer 68 includes the first layer 681 that covers the terminal portion front surface 641 of the terminal portion 64 and the second layer 682 disposed on the first layer 681. The thickness T21 of the first layer 681 is smaller than the thickness T22 of the second layer 682. The thickness T22 of the second layer 682 may represent the state before bonded to the connection terminal 20 illustrated in FIG. 5. The thickness T22 of the second layer 682 may be represented as the distance from the surface of the outer periphery of the first layer 681 to the highest point of the second layer 682 in the Z axis direction on the surface of the second layer 682. In one example, the thickness T21 of the first layer 681 may be lum or greater and less than or equal to 5 μm. In one example, the thickness T22 of the second layer 682 may be 10 μm or greater and less than or equal to 50 μm. In one example, the thickness T21 of the first layer 681 may be 3 μm. In one example, the thickness T22 of the second layer 682 may be 30 μm.

### (Manufacturing Method of Semiconductor Device)

Next, a manufacturing method of the semiconductor device 10 will be explained.

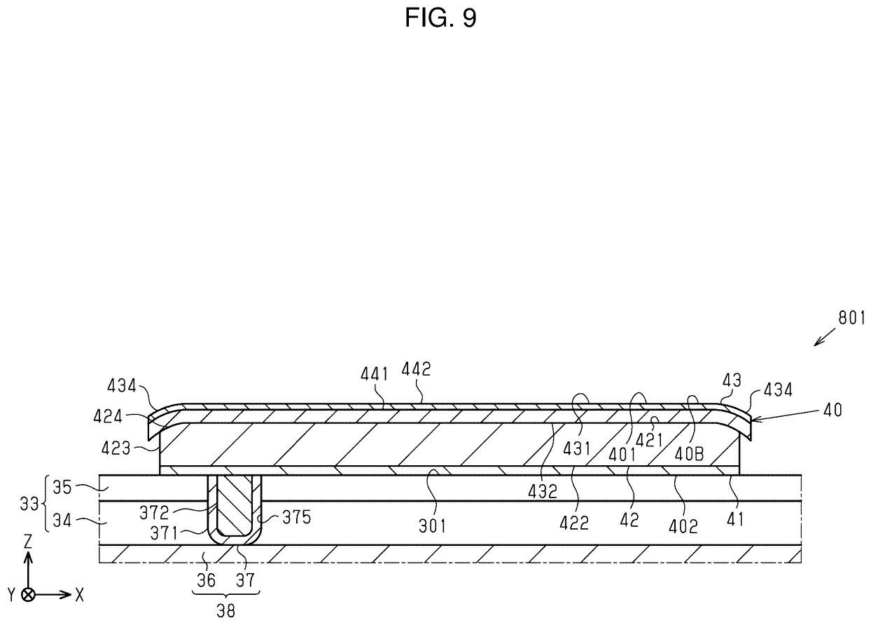

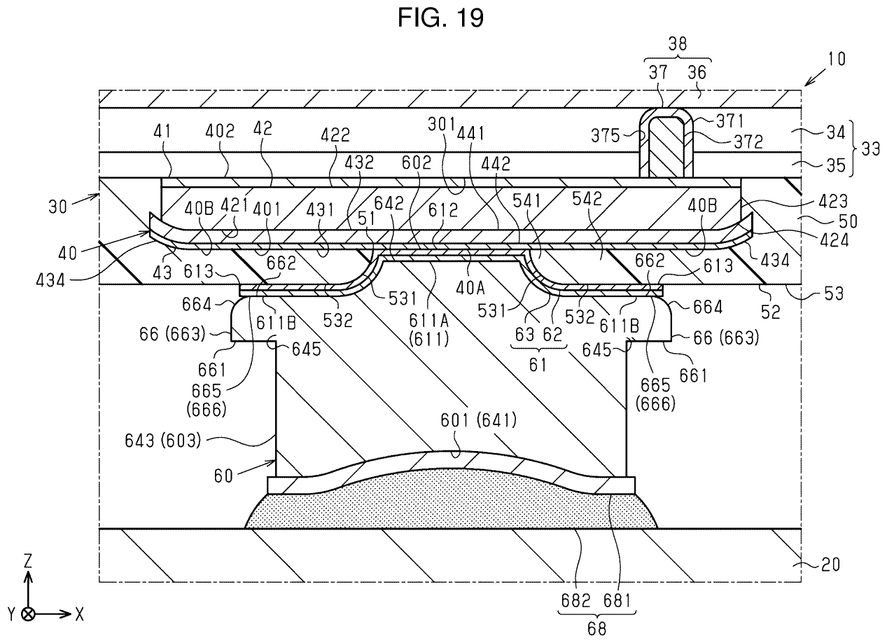

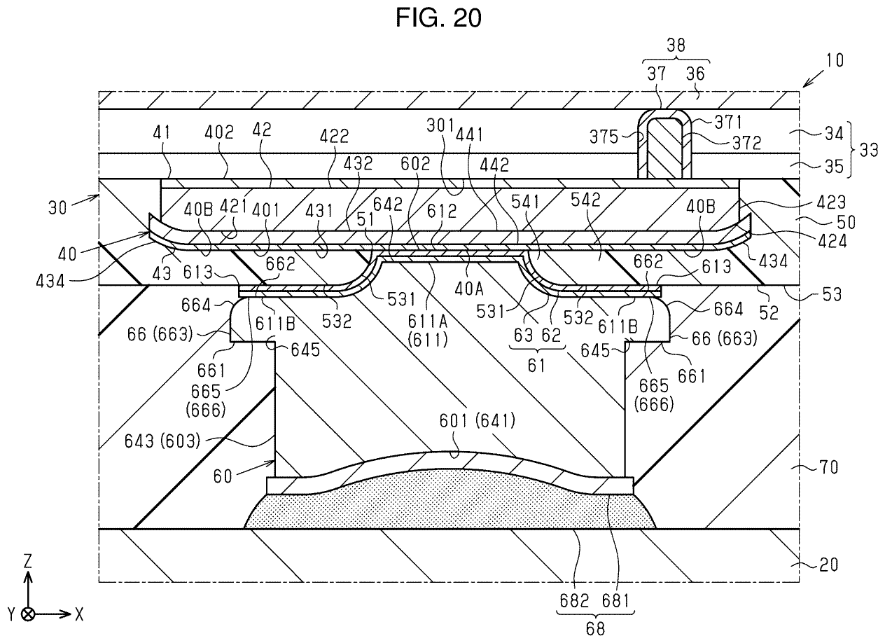

From FIG. 9 to FIG. 18, one example of the manufacturing method of the electrode terminal 60 in the semiconductor element 30 will be explained. Next, with reference to FIGS. 19 and 20, one example of the manufacturing method of the semiconductor device 10 including the semiconductor element 30 will be explained.

FIGS. 9 to 18 are cross-sectional views illustrating one example of the manufacturing process of the semiconductor element 30 illustrated in FIGS. 5 to 8. In FIGS. 9 to 18, one example of the manufacturing method of the parts related to the electrode terminal 60 will be mainly explained. FIGS. 9 to 18 are cross-sectional views corresponding to the cross section of FIGS. 5 and 7. FIG. 19 is a cross-sectional view illustrating the bonding between the semiconductor element 30 and the connection terminal 20. FIG. 20 is a cross-sectional view illustrating the formation of the sealing resin 70. For ease of explanation, in FIGS. 9 to 20, the same components as those in FIGS. 5 and 7 are given the same reference characters.

As shown in FIG. 9, a wafer 801 including the multi-layer wiring structure 38 is prepared. The uppermost surface of the multi-layer wiring structure 38 is constituted of the top insulating film 35 where a plurality of via wiring lines 37 are exposed.

As shown in FIG. 9, the manufacturing method of the semiconductor element 30 includes forming the electrode 40. The electrode 40 is formed on the top insulating film 35. In one example, the electrode 40 includes the wiring barrier film 41, the wiring electrode 42, and the cover electrode 43. The cover electrode 43 includes the first metal film 441 and the second metal film 442.

First, the wiring barrier film 41 and the seed layer is formed on the top insulating film 35. The barrier layer 41 and the seed layer may be formed by sputtering in one example. On the seed layer, a mask is formed. The mask has an opening in an area where the electrode 40 is to be formed. The mask is formed by forming a resist film having photosensitivity and forming an opening by performing photolithography on the resist film. The resist film is obtained by applying a photosensitive resin sheet or photosensitive resin liquid. Next, the wiring electrode 42 and the cover electrode 43 (the first metal film 441 and the second metal film 442) are formed within the opening of the mask. In one example, the wiring electrode 42 and the cover electrode 43 may be formed by plating (electrolytic plating, electroless plating). After removing the mask, the seed layer and the wiring barrier film 41 exposed from the wiring electrode 42 are removed. The seed layer and the wiring barrier film 41 may be removed by etching (such as the wet etching method).

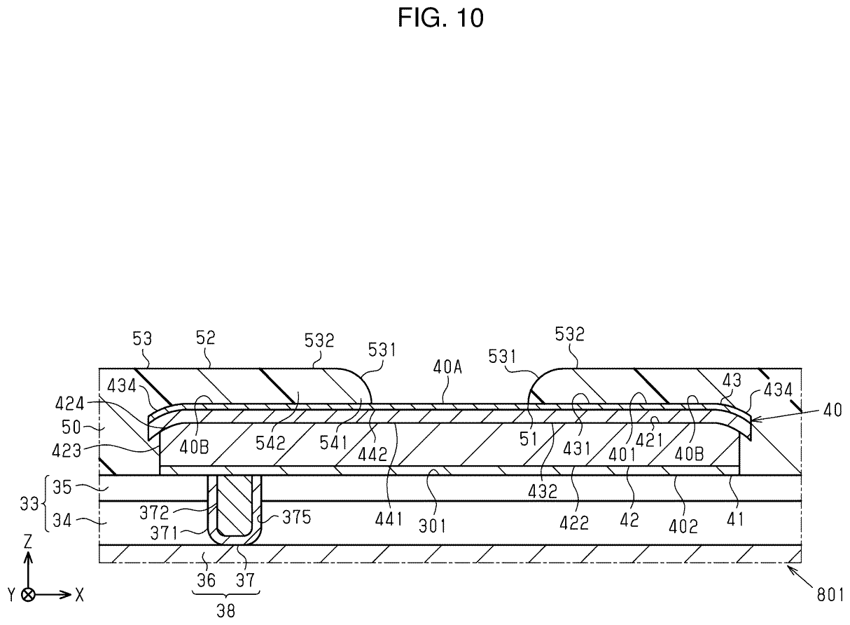

As shown in FIG. 10, the manufacturing method of the semiconductor element 30 includes forming the insulating layer 50. The insulating layer 50 includes the opening 51.

A photosensitive resin that will be the base of the insulating layer 50 is formed on the top insulating film 35. The photosensitive resin may be in the form of a liquid or a film. The photosensitive resin is formed to cover the electrode 40. The photosensitive resin undergoes photolithography and curing to form the insulating layer 50 including the opening 51 that exposes a part of the electrode 40. The electrode 40 includes an exposed part 40A exposed through the opening 51 of the insulating layer 50.

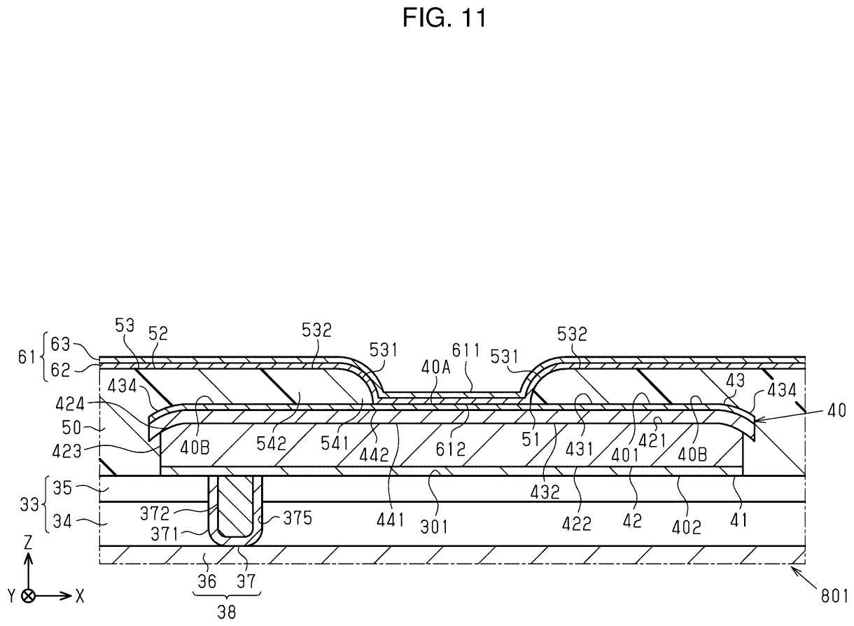

As shown in FIG. 11, the manufacturing method of the semiconductor element 30 includes forming the base layer 61. In one example, the base layer 61 includes the barrier layer 62 and the seed layer 63.

To form the base layer 61 on the exposed part 40A of the electrode 40 and the insulating layer 50, the barrier layer 62 is formed on the exposed part 40A of the electrode 40 and the insulating layer 50. In one example, the barrier layer 62 is made of a material containing Ti. In one example, the barrier layer 62 may be formed by sputtering. On the barrier layer 62, the seed layer 63 is formed. In one example, the seed layer 63 is made of a material containing Cu. In one example, the seed layer 63 may be formed by sputtering.

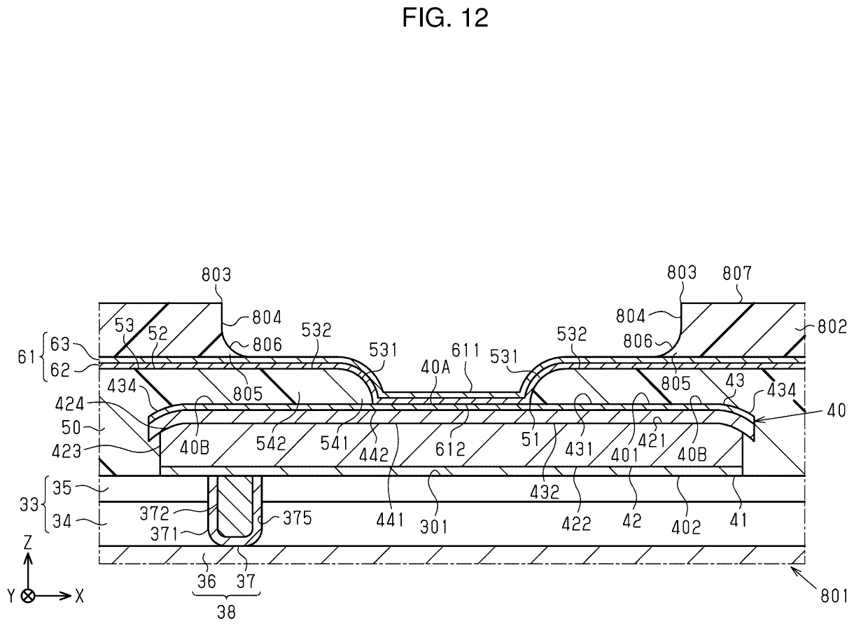

As shown in FIG. 12, the manufacturing method of the semiconductor element 30 includes forming the first mask 802. The first mask 802 is formed on the base layer 61. The first mask 802 includes a first opening 803 that exposes an area of the base layer 61 where the pedestal portion 66 of the electrode terminal 60 is to be formed.

In one example, the first mask 802 is obtained by forming a photosensitive resist film on the base layer 61 and forming the first opening 803 in the resist film by photolithography. In one example, the resist film is obtained by applying a liquid photosensitive resin. In one example, the resist film may be a positive type. The first opening 803 of the first mask 802 is formed to expose regions of the base layer 61 that are to become the first region 611A and the second region 611B. The thickness of the first mask 802 may be set according to the thickness T12 of the pedestal portion 66 shown in FIG. 8.

The first mask 802 includes an inner wall surface 804 that defines the first opening 803. The first mask 802 includes a protrusion 805 that protrudes from the inner wall surface 804 toward the inside of the first opening 803 at the lower end of the inner wall surface 804 closer to the seed layer 63. The protrusion 805 has a curved surface 806 that is curved into the protrusion 805. The protrusion 805 may be referred to as “footing” of the first mask 802. The curved surface 806 of the protrusion 805 may be formed by adjusting the photolithography conditions for the resist film. The curved surface 806 of the protrusion 805 forms the curved surface 664 of the pedestal portion 66 shown in FIGS. 5, 7, and 8.

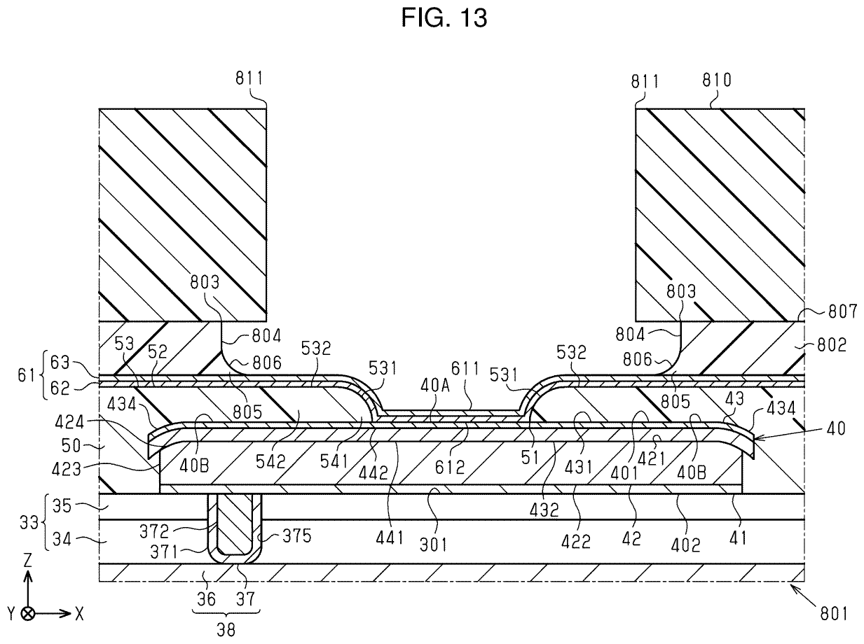

As shown in FIG. 13, the manufacturing method of the semiconductor element 30 includes forming the second mask 810. The second mask 810 is formed on the first mask 802. The second mask 810 is formed to cover the entire upper surface 807 of the first mask 802. The second mask 810 includes the second opening 811 that corresponds to the terminal portion 64 of the electrode terminal 60. The second opening 811 of the second mask 810 is formed to overlap the first opening 803 of the first mask 802 in the Z direction. Further, the second opening 811 of the second mask 810 is smaller than the first opening 803 of the first mask 802 in a plan view.

In one example, the second mask 810 is obtained by forming a photosensitive resist film on the first mask 802 and forming the second opening 811 in the resist film by photolithography. In one example, the resist film is obtained by applying a photosensitive resin sheet. In one example, the resist film may be a positive type. The second openings 811 of the second mask 810 are formed in accordance with the shape of the terminal portions 64.

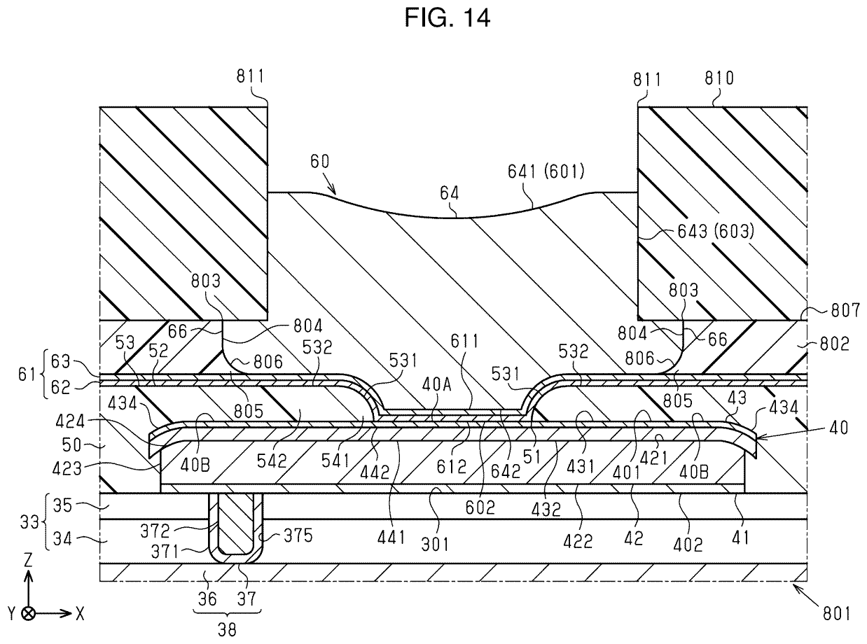

As shown in FIG. 14, the manufacturing method of the semiconductor element 30 includes forming the terminal portion 64 and the pedestal portion 66. In one example, the terminal portion 64 and the pedestal portion 66 are formed by precipitating a material for the terminal portion 64 and the pedestal portion 66 on the surface of the base layer 61 exposed from the first mask 802 by plating (e.g., electrolytic plating). The terminal portion 64 and the pedestal portion 66 are formed in the first opening 803 of the first mask 802 and in the second opening 811 of the second mask 810.

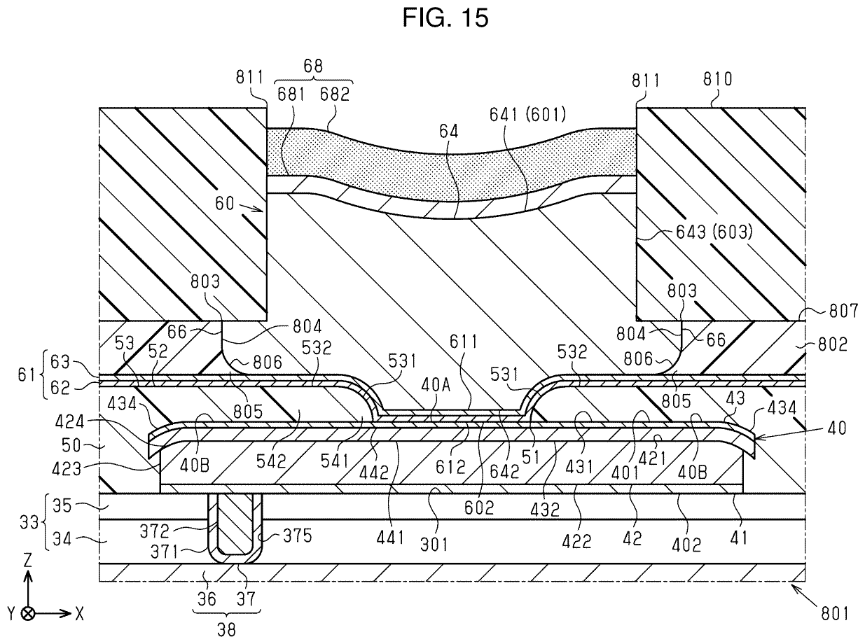

As shown in FIG. 15, the manufacturing method of the semiconductor element 30 includes forming the bonding layer 68. The bonding layer 68 includes the first layer 681 and the second layer 682. The first layer 681 is formed on the terminal portion 64, and the second layer 682 is formed on the first layer 681. In one example, the first layer 681 and the second layer 682 of the bonding layer 68 are formed by precipitating a material for the first layer 681 and a material for the second layer 682, in this order, within the second opening 811 of the second mask 810 by plating (e.g., electrolytic plating).

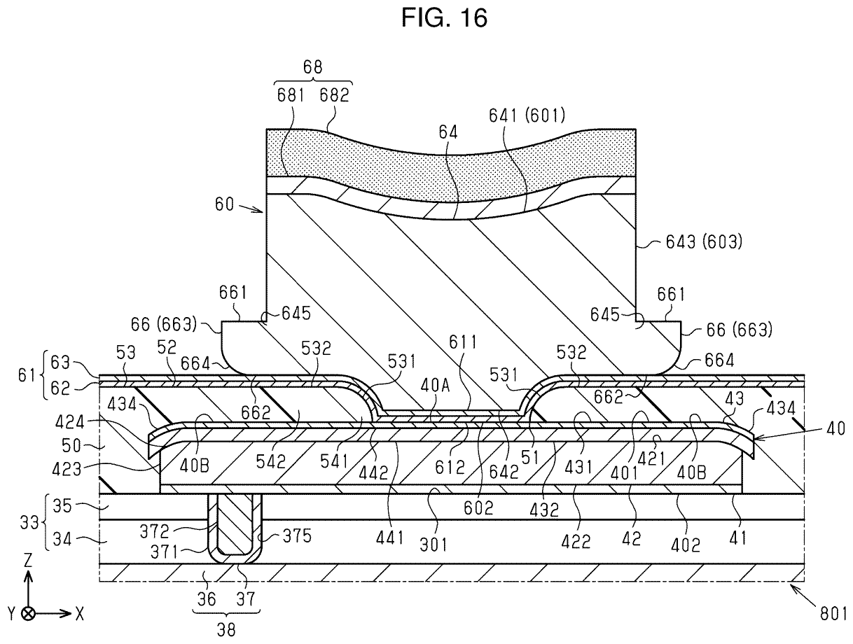

As shown in FIG. 16, the manufacturing method of the semiconductor element 30 includes removing the first mask 801 and the second mask 810. In one example, the first mask 802 and the second mask 810 are removed using a stripping liquid.

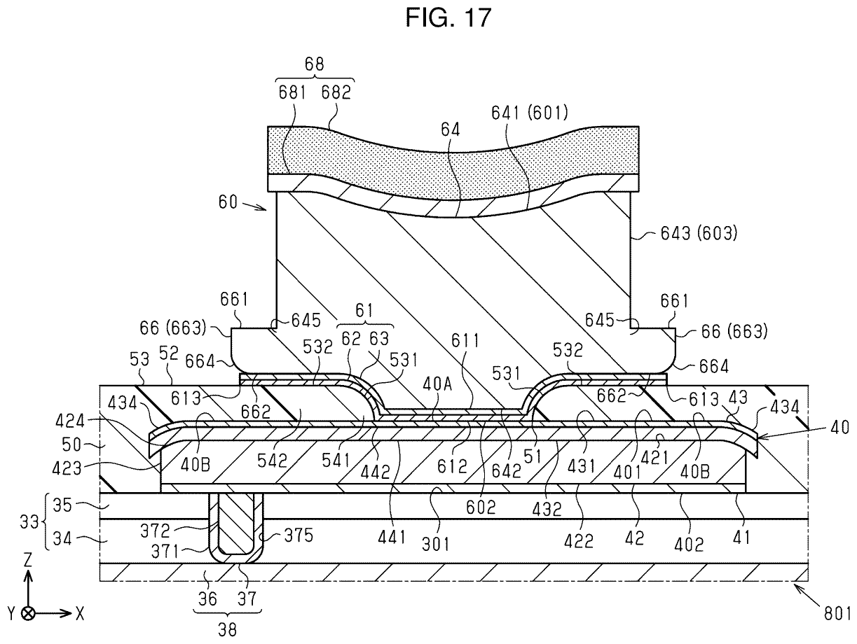

As shown in FIG. 17, the manufacturing method of the semiconductor element 30 includes forming the base layer 61. The base layer 61 shown in FIG. 17 is formed by removing the portions of the base layer 61 shown in FIG. 16 that are exposed outside the electrode terminals 60. The unnecessary portions of the base layer 61 are removed by etching (e.g., wet etching).

In this step, in addition to the unnecessary portions of the base layer 61, surfaces of the terminal portions 64 and the pedestal portions 66 are also removed. As a result, the terminal portion front surface 641 of the terminal portion 64 is located inside the terminal portion 64 rather than at the outer periphery of the first layer 681 of the bonding layer 68. The outer periphery 613 of the base layer 61 is located closer to the center of the terminal portion 64 than the pedestal portion side surface 663 of the pedestal portion 66 in a plan view.

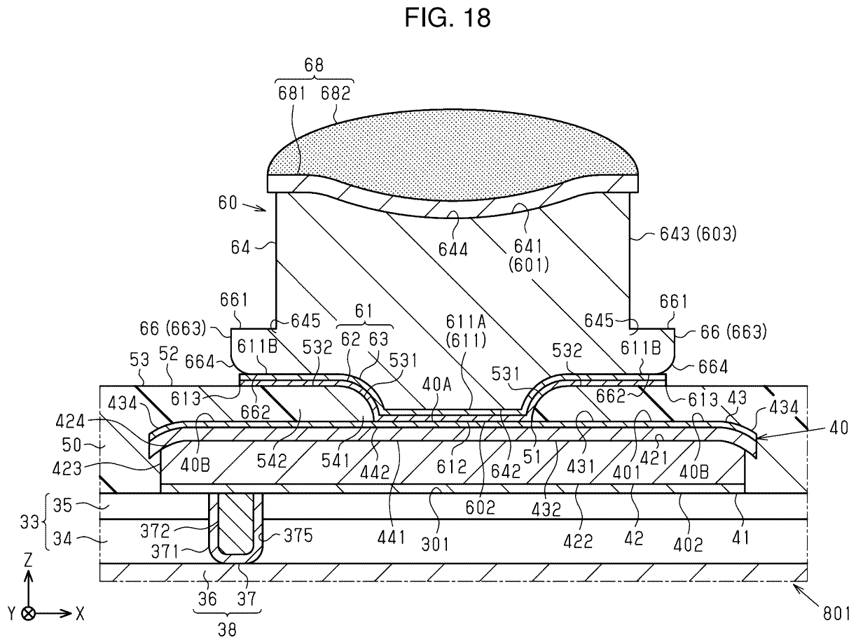

As shown in FIG. 18, the manufacturing method of the semiconductor element 30 includes forming the second layer 682 of the bonding layer 68. In one example, the second layer 682 of the bonding layer 68 is formed in a dome shape by the reflow process. The reflow process may be performed before removing the unnecessary portions of the base layer 61. The wafer 801 is then selectively cut. In this way, the semiconductor element 30 is manufactured.

As shown in FIG. 19, the manufacturing method of the semiconductor element 10 includes preparing the connection terminal 20. The connection terminal 20 is formed as part of a lead frame, for example.

The method for manufacturing the semiconductor device 10 includes mounting the semiconductor element 30 on the connection terminal 20. The semiconductor element 30 is placed on the connection terminal 20 with the electrode terminal 60 and the bonding layer 68 facing the connection terminal 20, and the electrode terminal 60 of the semiconductor element 30 is electrically connected to the connection terminal 20 by the second layer 682 of the bonding layer 68.

As shown in FIG. 20, the manufacturing method of the semiconductor element 10 includes forming the sealing resin 70. The sealing resin 70 seals the semiconductor element 30 and the connection terminal 20. In this way, the semiconductor element 10 is manufactured.

### Actions of Embodiments

Next, actions of the semiconductor element 30 and the semiconductor device 10 will be explained.

The semiconductor element 30 includes the electrode 40, the insulating layer 50, and the electrode terminal 60. The electrode 40 is disposed on the element front surface 301 that faces the Z direction. The insulating layer 50 covers the electrode 40, and includes the opening 51 through which a part of the electrode 40 is exposed. The electrode terminal 60 is in contact with the exposed part 40A of the electrode 40 exposed through the opening 51, and overlaps partially with the insulating layer 50 when viewed from the thickness direction.

The electrode terminal 60 includes the terminal portion 64 and the pedestal portion 66. The terminal portion 64 is disposed across the exposed part 40A of the electrode 40 and the periphery 52 of the opening 51 in the insulating layer 50. The terminal portion 64 is in contact with the exposed part 40A. The terminal portion 64 includes the terminal portion rear surface 642 and terminal portion side surface 643. The terminal portion rear surface 642 is in contact with the exposed part 40A and the periphery 52. The terminal portion side surface 643 intersects with the terminal portion rear surface 642. The pedestal portion 66 protrudes outwardly from a part 645 of the terminal portion side surface 643 of the terminal portion 64 closer to the terminal portion rear surface 642. The pedestal portion 66 includes the pedestal portion rear surface 662, pedestal portion side surface 663, and curved surface 664. The pedestal portion rear surface 662 is in contact with the insulating layer 50. The pedestal portion side surface 663 intersects with the pedestal portion rear surface 662 and is located outside the terminal portion side surfaces 643. The curved surface 664 is disposed between the pedestal portion rear surface 662 and the pedestal portion side surface 663.

The semiconductor device 10 includes the semiconductor element 30, the connection terminal 20 connected to the electrode terminals 60 of the semiconductor element 30, and the sealing resin 70 that seals the semiconductor elements 30 and the connection terminal 20. Here, a semiconductor device and a semiconductor element that are comparison examples to the semiconductor device 10 and the semiconductor element 30 of the above embodiment will be described. In the description of the semiconductor device and semiconductor element of the comparison example, the same components as those of the semiconductor device 10 and semiconductor element 30 of the above embodiment will be given the same reference characters. The semiconductor element of the comparison example does not include the pedestal portion 66 of the above embodiment. In other words, the electrode terminal of the semiconductor element of the comparison example includes a corner between the terminal portion side surface 643 and the terminal portion rear surface 642. In the semiconductor device of the comparison example, stress from temperature changes in sealing resin 70 and stress from the remaining manufacturing process may concentrate in the vicinity of the corners in the electrode terminal of the semiconductor element of the comparison example. Such stress concentration can lead to the occurrence of cracks in the insulating layer 50, peeling of the sealing resin 70, and the like.

In the semiconductor element 30 of the above embodiment, the electrode terminal 60 includes the terminal portion 64 and the pedestal portion 66 that protrudes outward from the terminal portion side surface 643 of the terminal portion 64. The pedestal portion 66 includes the pedestal portion rear surface 662 facing the surface 53 of the insulating layer 50, the pedestal portion side surface 663 intersecting the pedestal portion rear surface 662, and the curved surface 664 formed between the pedestal portion rear surface 662 and the pedestal portion side surface 663. The sealing resin 70 fills up the space between the curved surface 664 of the pedestal portion 66 and the insulating layer 50. This curved surface 664 can mitigate the stress concentration at the ends of the pedestal portion 66 closer to the insulating layer 50. This makes it possible to suppress the occurrence of cracks in the insulating layer 50, peeling of the sealing resin 70, and the like. As a result, the reliability of the semiconductor device 10 can be improved.

In the semiconductor element 30 of the above embodiment, the electrode terminal 60 includes the terminal portion 64 and the pedestal portion 66 that protrudes outward from the terminal portion side surface 643 of the terminal portion 64. The electrode terminal 60 includes the base layer 61 that is in contact with both the exposed part 40A of the electrode 40 and the periphery 52 of the insulating layer 50. The terminal portion 64 and the pedestal portion 66 are in contact with the base layer 61.

In a test on the semiconductor element 30 such as a shear strength test, a force is applied to the electrode terminal 60 in a direction intersecting with the Z-axis direction, e.g., in the X-axis direction. For example, when forming the sealing resin 70 that seals the semiconductor element 30, a force is applied to the electrode terminal 60 in a direction intersecting with the Z-axis direction. If the electrode terminal does not include the pedestal portion 66 of the above embodiment, the force in the X-axis direction is applied directly to the terminal portion 64, which may cause the terminal portion 64 to peel off from the base layer 61. On the other hand, in the electrode terminal 60 of the above embodiment, when a force is applied to the terminal portion 64 in the X-axis direction, the tilting of the terminal portion 64 is restricted by the pedestal portion 66. This makes it possible to prevent the terminal portion 64 and the pedestal portion 66 from peeling off from the base layer 61. Because of this, the share strength of the electrode terminal 60 is enhanced, and as a result, the reliability of the semiconductor element 30 can be improved. Also, the semiconductor device 10 that includes this semiconductor element 30 can be improved.

The pedestal portion 66 has a frame shape that surrounds the opening. This makes it possible to suppress the peeling of the terminal portion 64 against the force applied in the direction that intersects with the Z axis direction. As a result, the reliability of the semiconductor device 30 can further be improved.

The electrode terminal 60 has a circular shape when viewed from the thickness direction. When the electrode terminal 60 is formed in a rectangular column shape, stress due to temperature changes in sealing resin 70 and remaining stress from the manufacturing process may be concentrated at the corners. Such stress concentration at the corners can lead to the occurrence of cracks in the insulating layer 70. In the semiconductor device 10 of the above embodiment, however, the electrode terminal 60 of the semiconductor element 30 is in a circular shape when viewed from the Z axis direction, and thus, the stress concentration in the electrode terminal 60 can be mitigated.

The base layer 61 includes the barrier layer 62 that is in contact with both the exposed portion 40A and the periphery 52 of the insulating layer 50, and the seed layer 63 having a lower surface 632 in contact with the barrier layer 62 and an upper surface 611 including the first region 611A and the second region 611B. This barrier layer 62 can mitigate stress applied to the insulating layer 50 from the electrode terminal 60.

The bonding layer 68 includes the first layer 681 disposed on the terminal front surface 601, and the second layer 682 disposed on the first layer 681. In one example, the first layer 681 is made of a material containing Ni. In one example, the second layer 682 is a solder layer made of a material containing Sn. Therefore, the electrode terminal 60 and the connection terminal 20 can be bonded to each other with ease by melting the second layer 682. Furthermore, by having the first layer 681 interposed between the terminal portion 64 of the electrode terminal 60 and the second layer 682 of the bonding layer 68, a chemical reaction between the terminal portion 64 containing Cu and the second layer 682 containing Sn can be suppressed.

### Effects of Embodiments

As described above, according to the semiconductor device 10 of the above embodiment, the following effects are achieved.

(1) The semiconductor element 30 includes the electrode 40, the insulating layer 50, and the electrode terminal 60. The electrode 40 is disposed on the element front surface 301 that faces the Z direction. The insulating layer 50 covers the electrode 40, and includes the opening 51 through which a part of the electrode 40 is exposed. The electrode terminal 60 is in contact with the exposed part 40A of the electrode 40 exposed through the opening 51, and overlaps partially with the insulating layer 50 when viewed from the thickness direction.

The electrode terminal 60 includes the terminal portion 64 and the pedestal portion 66. The terminal portion 64 is disposed across the exposed part 40A and the periphery 52 of the opening 51 in the insulating layer 50. The terminal portion 64 is in contact with the exposed part 40A. The terminal portion 64 includes the terminal portion rear surface 642 and terminal portion side surface 643. The terminal portion rear surface 642 is in contact with the exposed part 40A and the periphery 52. The terminal portion side surface 643 intersects with the terminal portion rear surface 642. The pedestal portion 66 protrudes outwardly from a part 645 of the terminal portion side surface 643 of the terminal portion 64 closer to the terminal portion rear surface 642. The pedestal portion 66 includes the terminal portion rear surface 662, pedestal portion side surface 663, and curved surface 664. The terminal portion rear surface 662 is in contact with the insulating layer 50. The pedestal portion side surface 663 intersects with the pedestal portion rear surface 662 and is located outside the terminal portion side surface 643. The curved surface 664 is disposed between the pedestal portion rear surface 662 and the pedestal portion side surface 663.

The semiconductor device 10 includes the semiconductor element 30, the connection terminal 20 connected to the electrode terminals 60 of the semiconductor element 30, and the sealing resin 70 that seals the semiconductor element 30 and the connection terminal 20. The electrode terminal 60 includes the terminal portion 64 and the pedestal portion 66 that protrudes outward from the terminal portion side surface 643 of the terminal portion 64. The pedestal portion 66 includes the pedestal portion rear surface 662 facing the surface 53 of the insulating layer 50, the pedestal portion side surface 663 intersecting the pedestal portion rear surface 662, and the curved surface 664 formed between the pedestal portion rear surface 662 and the pedestal portion side surface 663. This curved surface 664 can mitigate the stress concentration at the ends of the pedestal portion 66 closer to the insulating layer 50. This makes it possible to suppress the occurrence of cracks in the insulating layer 50, peeling of the sealing resin 70, and the like. As a result, the reliability of the semiconductor device 10 can be improved.

(2) In the semiconductor element 30 of the above embodiment, the electrode terminal 60 includes the terminal portion 64 and the pedestal portion 66 that protrudes outward from the terminal portion side surface 643 of the terminal portion 64. The electrode terminal 60 includes the base layer 61 that is in contact with both the exposed part 40A of the electrode 40 and the periphery 52 of the insulating layer 50. The terminal portion 64 and the pedestal portion 66 are in contact with the base layer 61.

In a test on the semiconductor element 30 such as a shear strength test, a force is applied to the electrode terminals 60 in a direction intersecting with the Z-axis direction, e.g., in the X-axis direction. For example, when forming the sealing resin 70 that seals the semiconductor element 30, a force is applied to the electrode terminal 60 in a direction intersecting with the Z-axis direction. If the electrode terminal does not include the pedestal portion 66 of the above embodiment, the force in the X-axis direction is applied directly to the terminal portion 64, which may cause the terminal portion 64 to peel off from the base layer 61. On the other hand, in the electrode terminal 60 of the above embodiment, when a force is applied to the terminal portion 64 in the X-axis direction, the tilting of the terminal portion 64 is restricted by the pedestal portion 66. This makes it possible to prevent the terminal portion 64 and the pedestal portion 66 from peeling off from the base layer 61. Because of this, the share strength of the electrode terminal 60 is enhanced, and as a result, the reliability of the semiconductor element 30 can be improved. Also, the semiconductor device 10 that includes this semiconductor element 30 can be improved.

(3) The pedestal portion 66 has a frame shape that surrounds the opening. This makes it possible to suppress the peeling of the terminal portion 64 again the force applied in the direction that intersects with the Z axis direction. As a result, the reliability of the semiconductor device 30 can further be improved.

(4) The electrode terminal 60 has a circular shape when viewed from the thickness direction. When the electrode terminal 60 is formed in a rectangular column shape, stress due to temperature changes in the sealing resin 70 and remaining stress from the manufacturing process may be concentrated at the corners. Such stress concentration at the corners can lead to the occurrence of cracks in the insulating layer 70. In the semiconductor device 10 of the above embodiment, however, the electrode terminal 60 of the semiconductor element 30 is in a circular shape when viewed from the Z axis direction, and thus, the stress concentration in the electrode terminal 60 can be mitigated.

(5) The base layer 61 includes the barrier layer 62 in contact with both the exposed portion 40A and the periphery 52 of the insulating layer 50, and the seed layer 63 having a lower surface 632 in contact with the barrier layer 62 and an upper surface 611 that includes the first region 611A and the second region 611B. This barrier layer 62 can mitigate stress applied to the insulating layer 50 from the electrode terminal 60.

(6) The bonding layer 68 includes the first layer 681 disposed on the terminal surface 601, and the second layer 682 disposed on the first layer 681. In one example, the first layer 681 is made of a material containing Ni. In one example, the second layer 682 is a solder layer made of a material containing Sn. Therefore, the electrode terminal 60 and the connection terminal 20 can be bonded to each other with ease by melting the second layer 682. Furthermore, by having the first layer 681 interposed between the terminal portion 64 of the electrode terminal 60 and the second layer 682 of the bonding layer 68, a chemical reaction between the terminal portion 64 containing Cu and the second layer 682 containing Sn can be suppressed.

### Modification Examples

The embodiment described above may be modified in the following manner. The embodiment described above and the respective modification examples may be combined with each other unless such a combination results in technical contradiction. In the following modification examples, parts common to the above embodiment will be given the same reference characters as the above embodiments and descriptions thereof will be omitted.

The configuration of the semiconductor device 10 may be modified as appropriate.

The terminal portion 64 may have any shape such as an elliptical shape, an oval shape, a polygonal shape in a plan view.

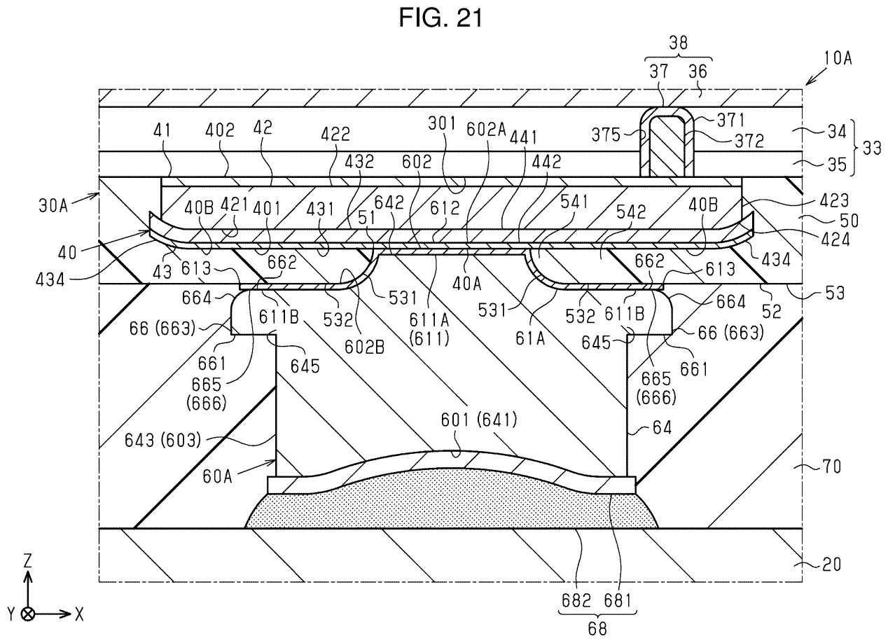

As shown in FIG. 21, a semiconductor device 10A includes a semiconductor element 30A. In this semiconductor element 30A, a base layer 61A of an electrode terminal 60A has a single-layer structure. In one example, the base layer 61A may be a seed layer. The base layer 61A may be made of a material containing at least one of Ti and Cu. In this semiconductor device 10A, stress concentration can be mitigated by the curved surface 664 of the pedestal portion 66 of the electrode terminal 60A. Also, in this semiconductor device 10A, the peeling of electrode terminal 60A can be suppressed by the pedestal portion 66 that is in contact with the base layer 61.

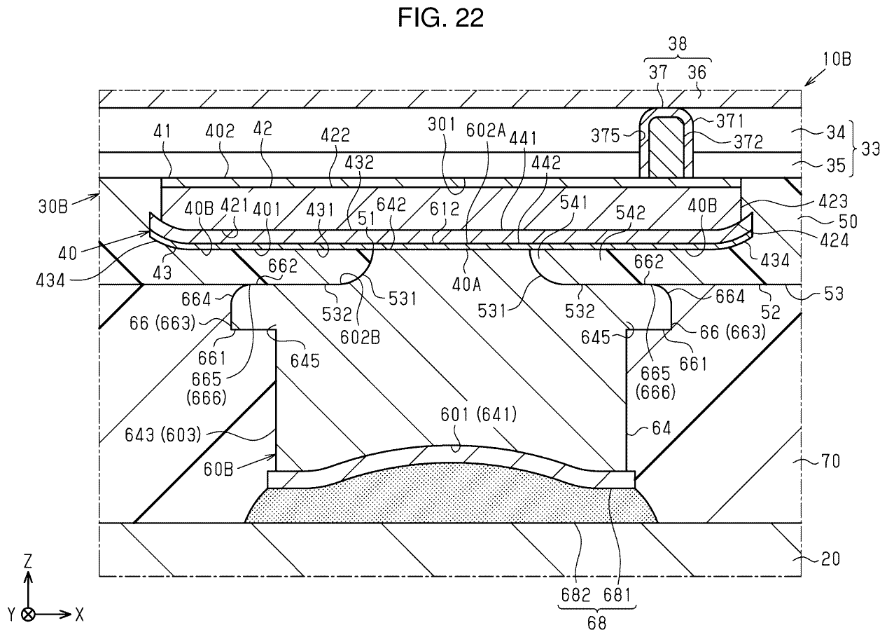

As shown in FIG. 22, a semiconductor device 10B includes a semiconductor element 30B. In this semiconductor element 30B, an electrode terminal 60B does not include the base layer 61 illustrated in FIG. 5 or the base layer 61A illustrated in FIG. 21. That is, in the electrode terminal 60B, the terminal portion 64 is in contact with both the exposed part 40A of the electrode 40B and the surface 53 of the periphery 52 of the insulating layer 50. The pedestal portion 66 is in contact with the surface 53 of the periphery 52 of the insulating layer 50. In this semiconductor device 10B, stress concentration can be mitigated by the curved surface 664 of the pedestal portion 66. Also, in this semiconductor device 10B, the peeling of electrode terminal 60B may be suppressed by the pedestal portion 66 that is in contact with the insulating layer 50.

The positional relationship between the outer periphery 613 of the base layer 61 of the electrode terminal 60 and the pedestal portion side surface 663 may be modified as appropriate. In one example, the outer periphery 613 of the base layer 61 may be located at the same position as the pedestal portion side surface 663 when viewed from the thickness direction. The outer periphery 613 of the base layer 61 may be located outside the terminal portion side surface 663.

The base layer 61 includes the barrier layer 62 and the seed layer 63. In one example, the side face of the barrier layer 62 may be flush with the side face of the seed layer 63. The side face of the barrier layer 62 may be located outside the side face of the seed layer 63. The side face of the barrier layer 62 may be located inside the side face of the seed layer 63.

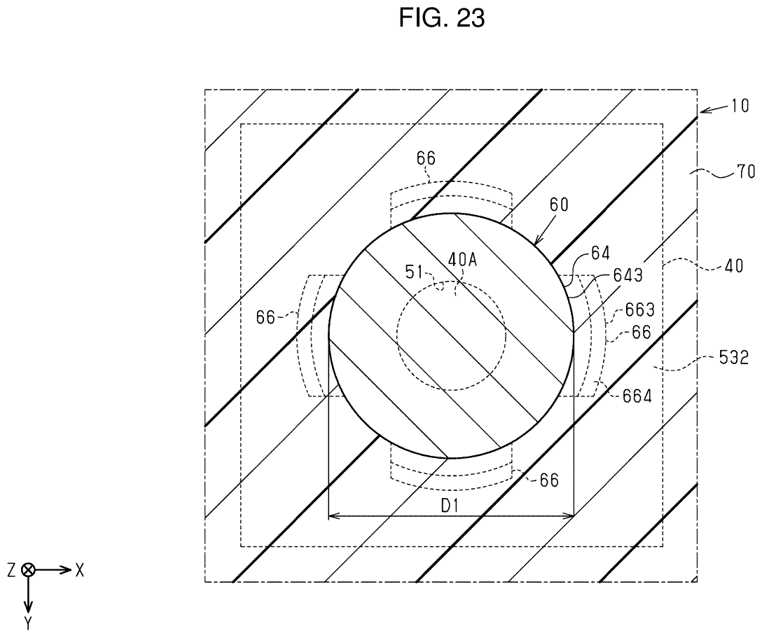

As illustrated in FIG. 23, a plurality of pedestal portions may be formed around the entire terminal portion 64 along the terminal portion side surface 643, spaced apart from each other.

The term “on” used in the present disclosure encompasses both “on” and “above” unless otherwise clearly indicated by the context. Thus, “the first layer is formed on the second layer” is intended to mean “the first layer is formed directly on the second layer and touching the second layer” in some embodiments, and “the first layer is formed above the second layer, not touching the second layer” in other embodiments. That is, the term “on” does not exclude any structure in which another layer is formed between the first layer and the second layer.

The Z-axis direction used in the present disclosure does not necessarily have to be the vertical direction, and does not necessarily have to completely coincide with the vertical direction. Therefore, in the various structures according to the present disclosure (for example, the structure illustrated in FIG. 1), the “up” and “down” in the Z-axis direction described in the present disclosure are not limited to “up” and “down” in the vertical direction. For example, the X-axis direction may be the vertical direction, or the Y-axis direction may be the vertical direction.

### SUPPLEMENTARY NOTES

The technical ideas that can be understood from this disclosure are described below. For the purpose of aiding understanding and not intending to be limiting, the components described in the supplementary notes are given the reference characters of the corresponding components in the embodiments. Reference characters are shown as examples to aid in understanding, and components described in each supplementary note should not be limited to the components indicated by the reference characters.

### Supplementary Note 1

A semiconductor element, including:
an electrode (40) disposed on an element front surface (301) that faces a thickness direction (Z);
an insulating layer (50) that covers the electrode (40) and has an opening (51) through which a part of the electrode (40) is exposed; and
an electrode terminal (60) that is in contact with an exposed part (40A) of the electrode (40) exposed through the opening (51) and that partially overlaps with the insulating layer (50) when viewed from the thickness direction (Z),
wherein the electrode terminal (60) includes:
a terminal portion (64) disposed across the exposed part (40A) and a periphery (52) of the opening (51) in the insulating layer (50) and electrically connected the electrode (40); and
a pedestal portion (66) connected to the terminal portion (64),
wherein the terminal portion (64) includes:
a terminal portion rear surface (642) that faces the exposed part (40A) and the periphery (52); and
a terminal portion side surface (643) that intersects with the terminal portion rear surface (642),
wherein the pedestal portion (66) protrudes outwardly from a part (645) of the terminal portion side surface (643) of the terminal portion (64) at a position closer to the terminal portion rear surface (642),
wherein the pedestal portion (66) includes:
a pedestal portion rear surface (662) that faces the insulating layer (50);
a pedestal portion side surface (663) intersecting with the pedestal portion rear surface (662) and located outside the terminal portion side surface (643); and
a curved surface (664) formed between the pedestal portion rear surface (662) and the pedestal portion side surface (663).

### Supplementary Note 2

The semiconductor element according to Supplementary Note 1, wherein the curved surface (664) is curving away from the pedestal portion (66).

### Supplementary Note 3

The semiconductor element according to Supplementary Note 1 or 2, wherein an outer periphery of the pedestal portion rear surface (662) is located between the terminal portion side surface (643) and the pedestal portion side surface (663) when viewed from the thickness direction (Z).

### Supplementary Note 4

The semiconductor element according to Supplementary Note 3, wherein a width (W11) of the pedestal portion rear surface (662) is greater than a distance between the pedestal portion side surface (663) and the outer periphery (665) of the pedestal portion rear surface (662), when viewed from the thickness direction (Z).

### Supplementary Note 5

The semiconductor device according to any one of Supplementary Notes 1 to 4, wherein the pedestal portion (66) is formed around the entire terminal portion (64) along the terminal portion side surface (643) when viewed from the thickness direction (Z).

### Supplementary Note 6

The semiconductor device according to any one of Supplementary Notes 1 to 5, wherein a plurality of the pedestal portions (66) are arranged along the terminal portion side surface (643), spaced apart from each other when viewed from the thickness direction (Z).

### Supplementary Note 7

The semiconductor device according to any one of Supplementary Notes 1 to 6, wherein the electrode terminal (60) includes a base layer (61) that is in contact with both the exposed part (40A) of the electrode (40) and the periphery (52) of the insulating layer (50), and wherein both the terminal portion (64) and the pedestal portion (66) are in contact with the base layer (61).

### Supplementary Note 8

The semiconductor element according to Supplementary Note 7, wherein an outer periphery (613) of the base layer (61) is located between the terminal portion side surface (643) and the pedestal portion side surface (663) when viewed from the thickness direction (Z).

### Supplementary Note 9

The semiconductor element according to Supplementary Note 8, wherein the outer periphery (613) of the base layer (61) is located outside the outer periphery (665) of the pedestal portion rear surface (662).

### Supplementary Note 10

The semiconductor element according to Supplementary Note 8 or 9, wherein the base layer (61) includes:
a barrier layer (62) that is in contact with both the exposed part (40A) of the electrode (40) and the periphery (52) of the insulating layer (50); and
a seed layer (63) that is in contact with the barrier layer,
wherein both the terminal portion (64) and the pedestal portion (66) are in contact with the seed layer (63).

### Supplementary Note 11

The semiconductor element according to Supplementary Note 10, wherein the inner periphery of the curved surface (664) is located inside an outer periphery (613) of the seed layer (63).

### Supplementary Note 12

The semiconductor element according to Supplementary Note 10 or 11, wherein a distance between the inner periphery of the curved surface (664) and the outer periphery (613) of the seed layer (63) is 2 μm.

### Supplementary Note 13

The semiconductor device according to any one of Supplementary Notes 10 to 12, wherein a width (W11) of the pedestal portion rear surface (662) is greater than the distance (L1) between the inner periphery of the curved surface (664) and the outer periphery (613) of the seed layer (63).

### Supplementary Note 14

The semiconductor device according to any one of Supplementary Notes 1 to 13, wherein the terminal portion (64) has a circular shape when viewed from the thickness direction (Z).

### Supplementary Note 15

The semiconductor device according to any one of Supplementary Notes 1 to 14, wherein the terminal portion (64) includes a terminal portion front surface (641) on the opposite side of the terminal portion rear surface (642).

### Supplementary Note 16

The semiconductor element according to Supplementary Note 15, wherein the terminal portion (64) includes a recessed portion (644) recessed from the terminal portion front surface (641) toward the electrode (40).

### Supplementary Note 17

The semiconductor device according to any one of Supplementary Notes 1 to 16, wherein a size (D1) of the terminal portion (64) is 10 μm or greater and less than or equal to 150 μm.

### Supplementary Note 18

The semiconductor device according to any one of Supplementary Notes 1 to 17, wherein a distance between the terminal portion side surface (643) and the pedestal portion side surface (643) in a direction orthogonal to the thickness direction (Z) is 10 μm or greater and less than or equal to 40 μm.

### Supplementary Note 19

The semiconductor device according to any one of Supplementary Notes 1 to 18, wherein a thickness of the pedestal portion (66) is 5 μm or greater and less than or equal to 20 μm.

### Supplementary Note 20

The semiconductor element according to Supplementary Note 15 or 16, wherein the electrode terminal (60) includes a bonding layer (68) disposed on the terminal portion front surface (641).

### Supplementary Note 21

The semiconductor element according to Supplementary Note 20, wherein the bonding layer (68) includes a first layer (681) disposed on the terminal portion front surface (641), and a second layer (682) disposed on the first layer (681).

### Supplementary Note 22

The semiconductor element according to Supplementary Note 21, wherein a thickness (T2) of the first layer (681) is smaller than a thickness (T2) of the second layer (682).

### Supplementary Note 23

A semiconductor device, including:
a semiconductor element (30) including an electrode terminal (60);
a plurality of connection terminals (20) electrically connected to the electrode terminal (60) of the semiconductor element (30);
a sealing resin (70) that seals the semiconductor element (30) and the plurality of connection terminals (20),
wherein the semiconductor element (30) includes:
an electrode (40) disposed on an element surface (301) that faces a thickness direction (Z),
an insulating layer (50) that covers the electrode (40) and has an opening (51) through which a part of the electrode (40) is exposed; and
the electrode terminal (60) that is in contact with an exposed part (40A) of the electrode (40) exposed through the opening (51) and that partially overlaps with the insulating layer (50) when viewed from the thickness direction (Z),
wherein the electrode terminal (60) includes:
a terminal portion (64) disposed across the exposed part (40A) and a periphery (52) of the opening (51) in the insulating layer (50) and electrically connected the electrode (40); and
a pedestal portion (66) connected to the terminal portion (64),
wherein the terminal portion (64) includes:
a terminal portion rear surface (642) that faces the exposed part (40A) and the periphery (52); and
a terminal portion side surface (643) that intersects with the terminal portion rear surface (642),
wherein the pedestal portion (66) protrudes outwardly from a part of the terminal portion side surface (643) of the terminal portion (64) at a position closer to the terminal portion rear surface (642),
wherein the pedestal portion (66) includes:
a pedestal portion rear surface (662) that faces the insulating layer (50);
a pedestal portion side surface (663) intersecting with the pedestal portion rear surface (662) and located outside the terminal portion side surface (643); and
a curved surface (664) disposed between the pedestal portion rear surface (662) and the pedestal portion side surface (663).
wherein the sealing resin (70) fills up a space between the curved surface (664) of the pedestal portion (66) and the insulating layer (50).

The descriptions above are merely illustrative. Those skilled in the art may recognize that many more possible combinations and permutations are possible other than the components and methods (manufacturing processes) enumerated for purposes of illustrating the technology of the present disclosure. The present disclosure is intended to embrace any alternatives, modifications, and variations that fall within the scope of the present disclosure, including the claims.

What is claimed is:

1. A semiconductor element, comprising:
an electrode disposed on an element front surface that faces a thickness direction;
an insulating layer that covers the electrode and has an opening through which a part of the electrode is exposed; and
an electrode terminal that is in contact with an exposed part of the electrode exposed through the opening and that partially overlaps with the insulating layer when viewed from the thickness direction,
wherein the electrode terminal includes:
a terminal portion disposed across the exposed part and a periphery of the opening in the insulating layer and electrically connected the electrode; and
a pedestal portion connected to the terminal portion,
wherein the terminal portion includes:
a terminal portion rear surface that faces the exposed part and the periphery; and
a terminal portion side surface that intersects with the terminal portion rear surface,
wherein the pedestal portion protrudes outwardly from a part of the terminal portion side surface of the terminal portion, and
wherein the pedestal portion includes:
a pedestal portion rear surface that faces the insulating layer;
a pedestal portion side surface intersecting with the pedestal portion rear surface and located outside the terminal portion side surface; and
a curved surface disposed between the pedestal portion rear surface and the pedestal portion side surface.

2. The semiconductor element according to claim 1, wherein the curved surface is curves away from the pedestal portion.

3. The semiconductor element according to claim 1, wherein an outer periphery of the pedestal portion rear surface is located between the terminal portion side surface and the pedestal portion side surface when viewed from the thickness direction.

4. The semiconductor element according to claim 3, wherein a width of the pedestal portion rear surface is greater than a distance between the pedestal portion side surface and the outer periphery of the pedestal portion rear surface when viewed from the thickness direction.

5. The semiconductor element according to claim 1, wherein the pedestal portion is formed around an entirety of the terminal portion along the terminal portion side surface when viewed from the thickness direction.

6. The semiconductor element according to claim 1, wherein a plurality of the pedestal portions are arranged along the terminal portion side surface, spaced apart from each other when viewed from the thickness direction.

7. The semiconductor element according to claim 1, wherein the electrode terminal includes a base layer that is in contact with both the exposed part of the electrode and a periphery of the insulating layer, and
wherein both the terminal portion and the pedestal portion are in contact with the base layer.

8. The semiconductor element according to claim 7, wherein an outer periphery of the base layer is located between the terminal portion side surface and the pedestal portion side surface when viewed from the thickness direction.

9. The semiconductor element according to claim 8, wherein the outer periphery of the base layer is located outside an outer periphery of the pedestal portion rear surface.

10. The semiconductor element according to claim 8, wherein the base layer includes:
a barrier layer that is in contact with both the exposed part of the electrode and the periphery of the insulating layer; and
a seed layer that is in contact with the barrier layer,
wherein both the terminal portion and the pedestal portion are in contact with the seed layer.

11. The semiconductor element according to claim 10, wherein an inner periphery of the curved surface is located inside an outer periphery of the seed layer.

12. The semiconductor element according to claim 10, wherein a distance between an inner periphery of the curved surface and an outer periphery of the seed layer is 2 μm.

13. The semiconductor element according to claim 10, wherein a width of the pedestal portion rear surface is greater than a distance between an inner periphery of the curved surface and an outer periphery of the seed layer.

14. The semiconductor element according to claim 1, wherein the terminal portion has a circular shape when viewed from the thickness direction.

15. The semiconductor element according to claim 1, wherein the terminal portion includes a terminal portion front surface on an opposite side of the terminal portion rear surface.

16. The semiconductor element according to claim 15, wherein the terminal portion includes a recessed portion recessed from the terminal portion front surface into the electrode.

17. The semiconductor element according to claim 1, wherein a size of the terminal portion is 10 μm or greater and less than or equal to 150 μm.

18. The semiconductor element according to claim 1, wherein a distance between the terminal portion side surface and the pedestal portion side surface in a direction orthogonal to the thickness direction is 10 μm or greater and less than or equal to 40 μm.

19. The semiconductor element according to claim 15, wherein the electrode terminal includes a bonding layer disposed on the terminal portion front surface.

20. A semiconductor device, comprising:
a semiconductor element including an electrode terminal;
a plurality of connection terminals electrically connected to the electrode terminal of the semiconductor element;
a sealing resin that seals the semiconductor element and the plurality of connection terminals,
wherein the semiconductor element includes:
an electrode disposed on an element surface that faces a thickness direction;
an insulating layer that covers the electrode and has an opening through which a part of the electrode is exposed; and
the electrode terminal that is in contact with an exposed part of the electrode exposed through the opening and that partially overlaps with the insulating layer when viewed from the thickness direction,
wherein the electrode terminal includes:
a terminal portion disposed across the exposed part and a periphery of the opening in the insulating layer and electrically connected the electrode; and
a pedestal portion connected to the terminal portion,
wherein the terminal portion includes:
a terminal portion rear surface that faces the exposed part and the periphery; and
a terminal portion side surface that intersects with the terminal portion rear surface,
wherein the pedestal portion protrudes outwardly from a part of the terminal portion side surface of the terminal portion,
wherein the pedestal portion includes:
a pedestal portion rear surface that faces the insulating layer;
a pedestal portion side surface intersecting with the pedestal portion rear surface and located outside the terminal portion side surface; and
a curved surface formed between the pedestal portion rear surface and the pedestal portion side surface, and
wherein the sealing resin fills up a space between the curved surface of the pedestal portion and the insulating layer.
